(19) United States
(12) Patent Application Publication
(10) Pub. No.: US 2025/0123559 A1
(43) Pub. Date: Apr. 17, 2025

(54) Resist Material And Patterning Process

(71) Applicant: SHIN-ETSU CHEMICAL CO., LTD., Tokyo (JP)

(72) Inventor: Yutaro OTOMO, Joetsu-shi (JP)

(73) Assignee: SHIN-ETSU CHEMICAL CO., LTD., Tokyo (JP)

(21) Appl. No.: 18/909,129

(22) Filed: Oct. 8, 2024

(30) Foreign Application Priority Data
Oct. 13, 2023 (JP) 2023-177868

(51) Int. Cl. G03F 7/021; G03F 7/004

(52) U.S. Cl. CPC G03F 7/0212; G03F 7/0045

(57) ABSTRACT

The present invention is a resist material containing: a base polymer (P) containing a repeating unit (A) containing a reactive group and represented by the following formula (a1) or (a2), and a repeating unit (B) having an acid-decomposable group; a crosslinking agent having a structure represented by the following formula (1); a thermal acid generator; a photodecomposable quencher represented by the following formula (2); and an organic solvent. This can provide: a resist material having little edge roughness, little size variation, excellent resolution, and excellent heat resistance; and a patterning process.

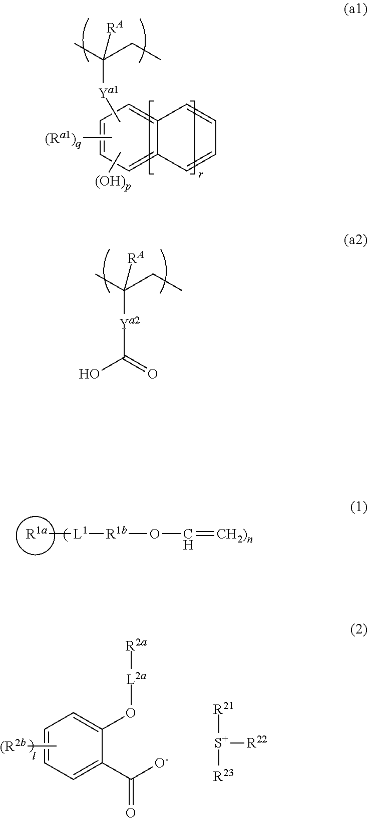

### TECHNICAL FIELD

The present invention relates to: a resist material; and a patterning process.

### BACKGROUND ART

As LSIs advance toward higher integration and higher processing speed, miniaturization of pattern rule is progressing rapidly. This is because the spread of high-speed communication of 5 G and artificial intelligence (AI) has progressed, and high-performance devices for processing these are needed. As a cutting-edge technology for miniaturization, 5-nm node devices have been mass-produced by extreme ultraviolet ray (EUV) lithography at a wavelength of 13.5 nm. Furthermore, studies are also in progress on employing EUV lithography in next-generation 3-nm node and the following-generation 2-nm node devices.

In lithography using a DUV light source, i.e., KrF and ArF excimer laser, chemically amplified resists have realized high-sensitivity and high-resolution lithography, and have led miniaturization as a main resist used for actual production processes. The chemically amplified resist changes the solubility to a developing solution by using an acid generated from a photosensitizer by exposure as a catalyst to cause a reaction of a base polymer resin.

Also in the next generation lithography such as EUV, the chemically amplified resist has been widely considered, and is currently in commercial use. On the other hand, along with miniaturization, requirement for improvement in resist performance has become increasingly higher, and in particular, it is desired to suppress variation in resist pattern dimensions (LWR: Line Width Roughness) and improve resolution. Factors relating to LWR and resolution in chemically amplified resists include the diffusion length of generated acid, the molecular weight of the base polymer, the property of a dissolution rate change curve (dissolution contrast) relative to the exposure amount, etc.

To suppress the diffusion of an acid generated in an exposed portion to an unexposed portion, it is effective to add an acid diffusion controller. Meanwhile, to suppress the diffusion of a substance in a baking step after exposure (PEB: post-exposure baking), it is effective to raise the glass transition point (Tg) of the resist film. It is possible to raise the Tg by increasing the molecular weight of the base polymer, but on the other hand, there is a problem that roughness is degraded by the dissolution unit at the time of development increasing. To solve such problems, an attempt has been made to increase the molecular weight of a polymer by a crosslinking group having acid degradability. Patent Document 1 discloses a crosslinking polymer obtained by reacting a unit containing a carboxy group or a hydroxy group with a divinyl ether unit. On the other hand, crosslinking polymers generated by crosslinking of polymer chains have a significantly high molecular weight so that an aggregation of polymers is generated after long-term storage as a resist solution. Thus, a problem of an increased number of defects occurs. Patent Document 2 discloses a resist material containing a polymer having a reactive site and a monomer crosslinking agent. However, there is a problem that a crosslinking reaction between the crosslinking agent and the polymer does not proceed sufficiently in a baking process after application of the resist material onto a substrate, and remaining monomeric components adversely affect the lithography performance.

### CITATION LIST

### Patent Literature

Patent Document 1: JP 5562651 B2
Patent Document 2: WO 2018/079449 A1

### SUMMARY OF INVENTION

### Technical Problem

In a positive resist containing a crosslinking agent, a crosslinking reaction progresses in a prebaking process after resist application so that the molecular weight of the resist increases, and the resist is decomposed in a PEB process after exposure so that the molecular weight decreases. That is, the obtained resist film has a high molecular weight in unexposed portions and has a low molecular weight in exposed portions, and thus, dissolution contrast can be enhanced.

However, in conventional crosslinking agent-containing resists, the crosslinking reaction does not progress sufficiently in the baking process, so that a large amount of unreacted crosslinking agent components remains and may adversely affect the lithography performance.

The present invention has been made in view of the above-described circumstances. An object of the present invention is to provide: a resist material having little edge roughness, little size variation, excellent resolution, and excellent heat resistance; and a patterning process.

### Solution to Problem

To achieve the object, the present invention provides a resist material comprising:
a base polymer (P) containing a repeating unit (A) containing a reactive group and represented by the following formula (a1) or (a2), and a repeating unit (B) having an acid-decomposable group;
a crosslinking agent having a structure represented by the following formula (1);
a thermal acid generator;
a photodecomposable quencher represented by the following formula (2); and
an organic solvent,

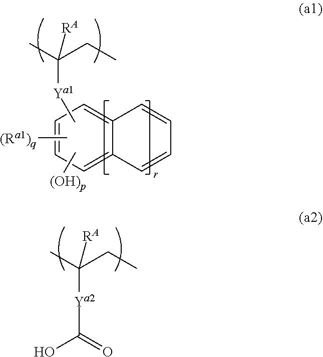

wherein each R^{A} independently represents a hydrogen atom or a methyl group, Y^{a1} and Y^{a2} each independently represent a single bond, a phenylene group, a naphthylene group, or a linking group having 1 to 14 carbon atoms and having an ester bond, an ether bond, an amide bond, or a lactone ring, R^{a1} represents a hydrogen atom, a fluorine atom, or a saturated hydrocarbyl group having 1 to 6 carbon atoms, R^{a1} and Y^{a1} optionally being bonded to each other to form a ring together with the carbon atoms on the aromatic ring bonded thereto, “p” represents 1 or 2, “q” represents an integer of 0 to 4, 1≤p+q≤5, and “r” represents 0 or 1,

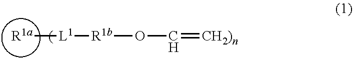

wherein R^{1a} represents an organic group optionally having a substituent, L¹ represents a linking group selected from a single bond, an ester bond, and an ether bond, R^{1b} represents a single bond or a divalent organic group, and “n” represents an integer of 2 to 4,

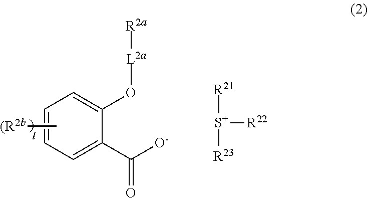

wherein R²¹ to R²³ each independently represent a monovalent hydrocarbon group having 1 to 20 carbon atoms and optionally containing a heteroatom, any two of R²¹, R²², and R²³ optionally being bonded to each other to form a ring together with the sulfur atom bonded thereto, “I” represents an integer of 0 to 4, R^{2b} represents a halogen atom, a hydroxy group, a nitro group, a hydrocarbon group having 1 to 20 carbon atoms and optionally having a substituent, an alkoxy group having 1 to 18 carbon atoms and optionally having a substituent, an amino group optionally having a substituent, or a phenyl group optionally having a substituent, when “I” is 2 or more, the R^{2b}s optionally being different from each other, L^{2a} represents a single bond, an ester bond, or a divalent linking group having 1 to 8 carbon atoms, and R^{2a} represents a hydrogen atom or a hydrocarbon group having 1 to 18 carbon atoms and optionally having a substituent, R^{2a} and R^{2b} optionally being bonded to each other to form a ring together with the carbon atoms bonded thereto.

Such a resist material has little edge roughness and size variation, excellent resolution, and favorable heat resistance.

The base polymer (P) preferably contains a repeating unit (C) having a structural site which is decomposed by irradiation with an active ray or a radiant ray to generate an acid.

Thus, the dissolution contrast between an exposed portion and an unexposed portion can be further improved.

In this case, it is more preferable that the repeating unit (C) contained in the base polymer (P) is represented by the following formula (c),

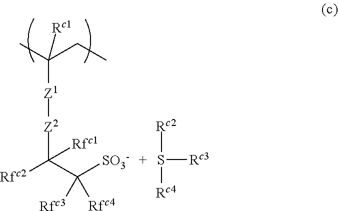

wherein R^{c1} represents a hydrogen atom or a methyl group; Z¹ represents a single bond or an ester bond; Z² represents a single bond or a divalent organic group having 1 to 20 carbon atoms and optionally containing an ester bond, an ether bond, a lactone ring, an amide bond, a sultone ring, or an iodine atom; Rf^{c1} to Rf^{c4} each independently represent a hydrogen atom, a fluorine atom, or a trifluoromethyl group, provided that at least one of Rf^{c1} to Rf^{c4} contains a fluorine atom; and R^{c2} to R^{c4} each independently represent a monovalent hydrocarbon group having 1 to 20 carbon atoms and optionally containing a heteroatom, any two of R^{c2}, R^{c3}, and R^{c4} optionally being bonded to each other to form a ring together with the sulfur atom bonded thereto.

As the repeating unit (C), one having such a structure can be used suitably.

The repeating unit (B) contained in the base polymer (P) is preferably represented by the following formula (b),

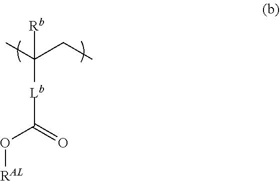

wherein R^{b} represents a hydrogen atom or a methyl group; L^{b} represents a single bond or a divalent linking group having 1 to 15 carbon atoms and including at least one of a phenylene group, a naphthylene group, an ester bond, an ether bond, a lactone ring, an amide group, and a heteroatom; and R^{AL} represents an acid-labile group.

As the repeating unit (B), one having such a structure can be used suitably.

It is preferable that the repeating unit (A) contained in the base polymer (P) is represented by the formula (a1), and is contained at a percentage of 30 mol % or more based on a total amount of the repeating units in the base polymer (P).

Such a base polymer (P) has a high reaction efficiency with the crosslinking agent. Thus, an excellent lithography property can be achieved.

The present invention also provides a patterning process comprising the steps of:
forming a resist film on a substrate by using the above-described resist material;
exposing the resist film to a high-energy beam; and
developing the exposed resist film by using a developer.

According to such a patterning process, it is possible to obtain a pattern having little edge roughness, little size variation, and excellent resolution.

In this event, in the step of forming the resist film, a baking temperature is preferably set to 130° C. or higher.

When the baking temperature is set to 130° C. or higher, a weak acid is generated from the thermal acid generator, and the crosslinking reaction progresses efficiently with the weak acid as a catalyst.

### Advantageous Effects of Invention

The inventive resist material (composition), which contains a polymer containing a certain repeating unit, a certain crosslinking agent, a thermal acid generator, a certain sulfonium salt, and an organic solvent, allows small edge roughness and size variation, and has excellent resolution and excellent heat resistance. The inventive resist material has such excellent properties, and therefore, has extremely high practicality, and in particular, is very useful for manufacturing very large-scale integrated circuits, and is very useful as a material for fine pattern formation of a photomask by EB writing or as a material for pattern formation for EB or EUV lithography. The inventive resist material can be applied to, for example, not only lithography in the formation of semiconductor circuits, but also for the formation of mask circuit patterns, micro-machines, and the formation of thin-film magnetic head circuits.

### BRIEF DESCRIPTION OF DRAWINGS

FIG. 1 is a graph showing the contrast curves of the resist films of Example 3-9 and Comparative Example 3-10.

### DESCRIPTION OF EMBODIMENTS

As stated above, it has been desired to develop: a resist material having small edge roughness, small variation in size, excellent resolution, and favorable heat resistance; and a patterning process.

The present inventor has studied earnestly, and found out that the above-described problems can be solved by a resist composition containing: a base polymer having a particular structural unit; a particular crosslinking agent; a thermal acid generator; and a sulfonium salt having a particular structure.

That is, the present invention is a resist material comprising: a base polymer (P) containing a repeating unit (A) containing a reactive group and represented by the following formula (a1) or (a2), and a repeating unit (B) having an acid-decomposable group;
a crosslinking agent having a structure represented by the following formula (1);
a thermal acid generator;
a photodecomposable quencher represented by the following formula (2); and
an organic solvent,

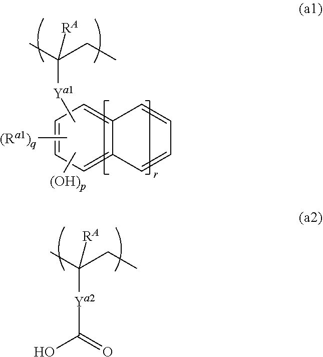

wherein each R^{A} independently represents a hydrogen atom or a methyl group, Y^{a1} and Y^{a2} each independently represent a single bond, a phenylene group, a naphthylene group, or a linking group having 1 to 14 carbon atoms and having an ester bond, an ether bond, an amide bond, or a lactone ring, R^{a1} represents a hydrogen atom, a fluorine atom, or a saturated hydrocarbyl group having 1 to 6 carbon atoms, R^{a1} and Y^{a1} optionally being bonded to each other to form a ring together with the carbon atoms on the aromatic ring bonded thereto, “p” represents 1 or 2, “q” represents an integer of 0 to 4, 1≤p+q≤5, and “r” represents 0 or 1,

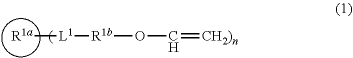

wherein R^{1a} represents an organic group optionally having a substituent, L¹ represents a linking group selected from a single bond, an ester bond, and an ether bond, R^{1b} represents a single bond or a divalent organic group, and “n” represents an integer of 2 to 4,

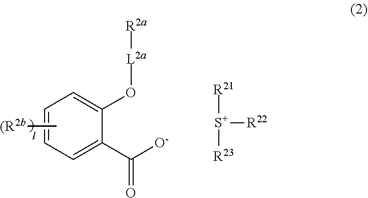

wherein R²¹ to R²³ each independently represent a monovalent hydrocarbon group having 1 to 20 carbon atoms and optionally containing a heteroatom, any two of R²¹, R²², and R²³ optionally being bonded to each other to form a ring together with the sulfur atom bonded thereto, “I” represents an integer of 0 to 4, R^{2b} represents a halogen atom, a hydroxy group, a nitro group, a hydrocarbon group having 1 to 20 carbon atoms and optionally having a substituent, an alkoxy group having 1 to 18 carbon atoms and optionally having a substituent, an amino group optionally having a substituent, or a phenyl group optionally having a substituent, when “I” is 2 or more, the R^{2b}s optionally being different from each other, L^{2a} represents a single bond, an ester bond, or a divalent linking group having 1 to 8 carbon atoms, and R^{2a} represents a hydrogen atom or a hydrocarbon group having 1 to 18 carbon atoms and optionally having a substituent, R^{2a} and R^{2b} optionally being bonded to each other to form a ring together with the carbon atoms bonded thereto.

Hereinafter, the present invention will be described in detail, but the present invention is not limited thereto.

### [Resist Material]

The inventive resist material (composition) contains: a base polymer (P) containing a repeating unit (A) having a reactive group and a repeating unit (B) having an acid-decomposable group; a certain crosslinking agent; a thermal acid generator; a certain sulfonium salt; and an organic solvent. When a film of this resist is formed on a wafer, a weak acid derived from the thermal acid generator is generated in a softbaking process. The molecular weight of the base polymer is increased by an addition reaction between the vinyl ether moiety of the crosslinking agent and the reactive group of the polymer while using such an acid as a catalyst. Such a crosslinked structure breaks down by the action of a strong acid component generated in an exposed portion, and the molecular weight of the polymer decreases, and therefore, the dissolution contrast between exposed and unexposed portions can be enhanced by the effect of not only change in the polarity of the base polymer but also change in the molecular weight.

### [Base Polymer (P)]

The base polymer in the present invention contains: a repeating unit (A) having a reactive group; and a repeating unit (B) having an acid-decomposable group. It is possible to form a positive pattern having high resolution by the unit (A) contributing to change in the molecular weight and the unit (B) contributing to change in the polarity.

The base polymer (P) contains a repeating unit (A) represented by the following formula (a1) or (a2).

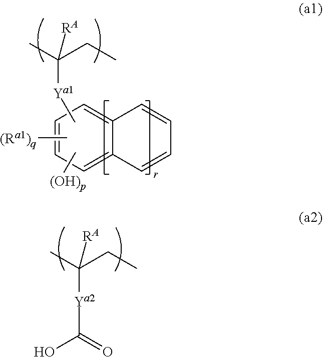

In the formulae, each R^{A} independently represents a hydrogen atom or a methyl group, Y^{a1} and Y^{a2} each independently represent a single bond, a phenylene group, a naphthylene group, or a linking group having 1 to 14 carbon atoms and having an ester bond, an ether bond, an amide bond, or a lactone ring, R^{a1} represents a hydrogen atom, a fluorine atom, or a saturated hydrocarbyl group having 1 to 6 carbon atoms, R^{a1} and Y^{a1} optionally being bonded to each other to form a ring together with the carbon atoms on the aromatic ring bonded thereto, “p” represents 1 or 2, “q” represents an integer of 0 to 4, 1≤p+q≤5, and “r” represents 0 or 1.

Examples of monomers to give a repeating unit (a1) include the following, but are not limited thereto.

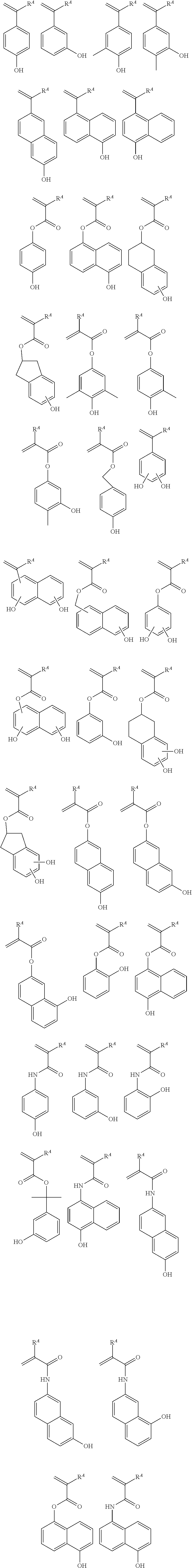

Examples of monomers to give a repeating unit (a2) include the following, but are not limited thereto.

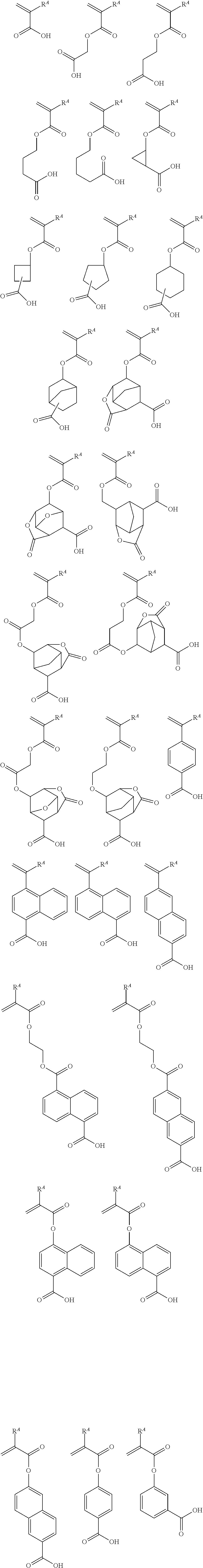

The repeating unit (A) having the reactive group is preferably represented by the formula (a1), and 30 mol % or more of the repeating unit (A) is preferably contained based on the total amount of the repeating units contained in the base polymer (P).

The repeating unit represented by the formula (a1) is preferably contained in an amount of 30 mol % or more and 90 mol % or less, more preferably 35 mol % or more and 85 mol % or less, more preferably 40 mol % or more and 80 mol % or less, and more preferably 50 mol % or more and 70 mol % or less relative to the base polymer (P).

When the contained amount of the repeating unit (a1) is 30 mol % or more, the reaction efficiency with the crosslinking agent is sufficient and there is no risk of a large amount of unreacted crosslinking agent components remaining in the system, so that excellent lithography performance can be provided. Therefore, the repeating unit (a1) is preferably contained at a percentage of 30 mol % or more.

Furthermore, the base polymer (P) contains a repeating unit (B) having an acid-decomposable group. Examples of the repeating unit (B) include those represented by the following formula (b).

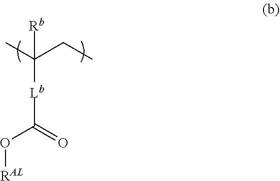

In the formula (b), R^{b} represents a hydrogen atom or a methyl group; L^{b} represents a single bond or a divalent linking group having 1 to 15 carbon atoms and including at least one of a phenylene group, a naphthylene group, an ester bond, an ether bond, a lactone ring, an amide group, and a heteroatom; and R^{AL} represents an acid-labile group.

Examples of monomers to give the repeating unit (B) include the following, but are not limited thereto.

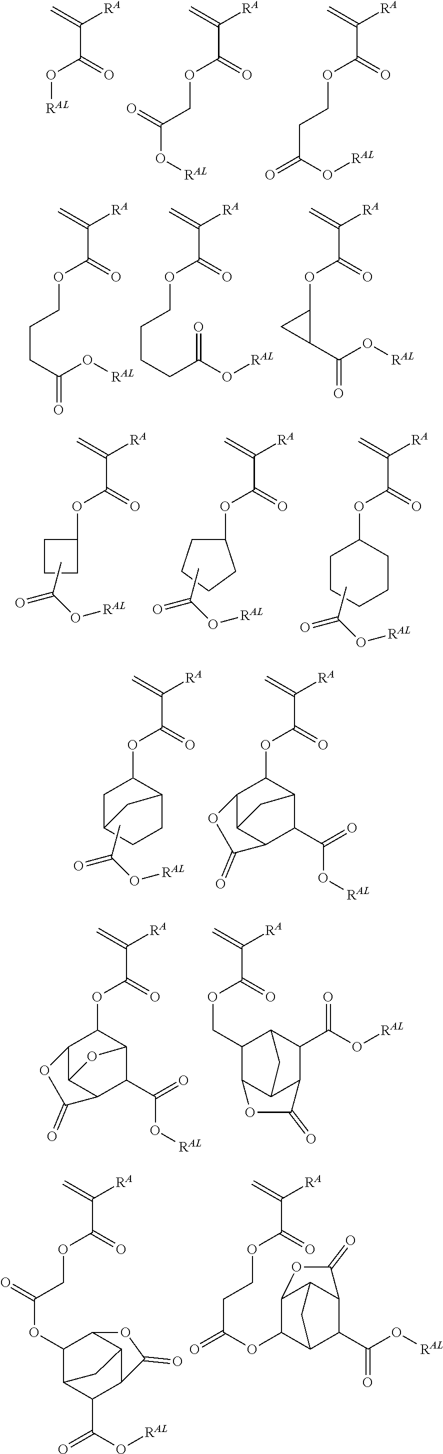

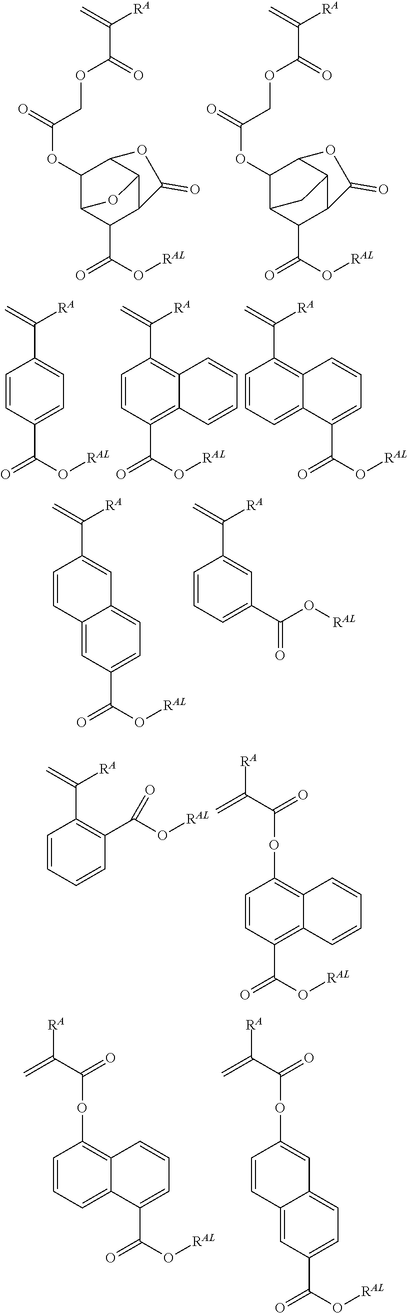

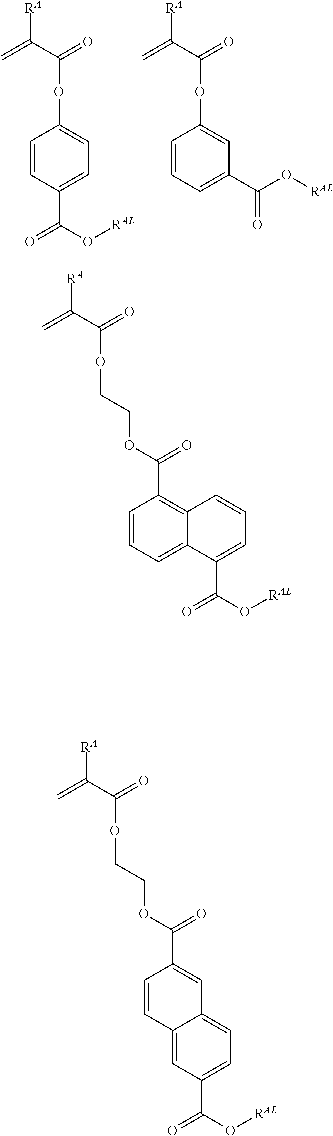

Examples of the acid-labile group represented by R^{AL} include groups represented by the following formulae (AL-1) to (AL-19), but are not limited thereto.

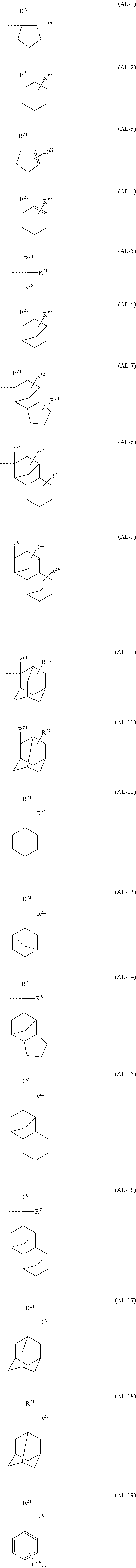

In the formulae, a broken line represents an attachment point.

In the formulae (AL-1) to (AL-19), each R^{L1} independently represents a saturated hydrocarbyl group having 1 to 8 carbon atoms or an aryl group having 6 to 20 carbon atoms. R^{L2} and R^{L4} each independently represent a hydrogen atom or a saturated hydrocarbyl group having 1 to 20 carbon atoms. R^{L3} represents an aryl group having 6 to 20 carbon atoms. The saturated hydrocarbyl group may be linear, branched, or cyclic. As the aryl group, a phenyl group or the like is preferable. R^{F} represents a fluorine atom or a trifluoromethyl group. “a” represents an integer of 1 to 5.

The base polymer (P) preferably contains a repeating unit (C) having a structural site which is decomposed by irradiation with an active ray or a radiant ray to generate an acid. The acid that is generated from the repeating unit (C) decomposes the acid-labile group that the repeating unit (B) has and the crosslinked structure. Accordingly, the polarity change and molecular weight reduction occur in the exposed part of the resist film, so that dissolution contrast with an unexposed part is improved. It is thought that, when the acid-generating unit is contained in the polymer, there is an effect of enhancing the uniformity of the acid concentration in the resist film by the diffusion of the generated acid being suppressed, and also by the aggregation of the acid generator being suppressed.

The repeating unit (C) is preferably represented by the following formula (c).

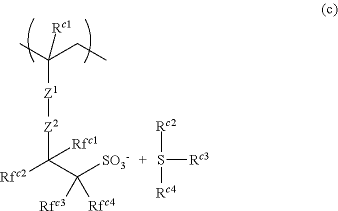

In the formula, R^{c1} represents a hydrogen atom or a methyl group; Z¹ represents a single bond or an ester bond; Z² represents a single bond or a divalent organic group having 1 to 20 carbon atoms and optionally containing an ester bond, an ether bond, a lactone ring, an amide bond, a sultone ring, or an iodine atom; Rf^{c1} to Rf^{c4} each independently represent a hydrogen atom, a fluorine atom, or a trifluoromethyl group, provided that at least one of Rf^{c1} to Rf^{c4} contains a fluorine atom; and R^{c2} to R^{c4} each independently represent a monovalent hydrocarbon group having 1 to 20 carbon atoms and optionally containing a heteroatom, any two of R^{c2}, R^{c3}, and R^{c4} optionally being bonded to each other to form a ring together with the sulfur atom bonded thereto.

In the formula, R^{c1} represents a hydrogen atom or a methyl group. Z¹ represents a single bond or an ester bond. Z² represents a single bond or a divalent organic group having 1 to 20 carbon atoms and optionally containing an ester bond, an ether bond, a lactone ring, an amide bond, a sultone ring, or an iodine atom. The divalent organic group may be linear, branched, or cyclic, and specific examples include: alkanediyl groups having 1 to 20 carbon atoms, such as a methanediyl group, an ethane-1,1-diyl group, an ethane-1,2-diyl group, a propane-1,2-diyl group, a propane-1,3-diyl group, a propane-2,2-diyl group, a butane-1,2-diyl group, a butane-1,3-diyl group, a butane-1,4-diyl group, a butane-2,2-diyl group, a butane-2,3-diyl group, a 2-methylpropane-1,3-diyl group, a pentane-1,5-diyl group, a hexane-1,6-diyl group, a heptane-1,7-diyl group, an octane-1,8-diyl group, a nonane-1,9-diyl group, and a decane-1,10-diyl group; cyclic saturated hydrocarbylene groups having 3 to 20 carbon atoms, such as a cyclopentanediyl group, a cyclohexanediyl group, a norbornanediyl group, and an adamantanediyl group; groups which are combinations of these groups; etc. Rf^{c1} to Rf^{c4} each independently represent a hydrogen atom, a fluorine atom, or a trifluoromethyl group, provided that at least one of Rf^{c1} to Rf^{c4} contains a fluorine atom.

Furthermore, the repeating unit (C) preferably contains an iodine atom.

Examples of anions of monomers to give the repeating unit (c) include the following, but are not limited thereto.

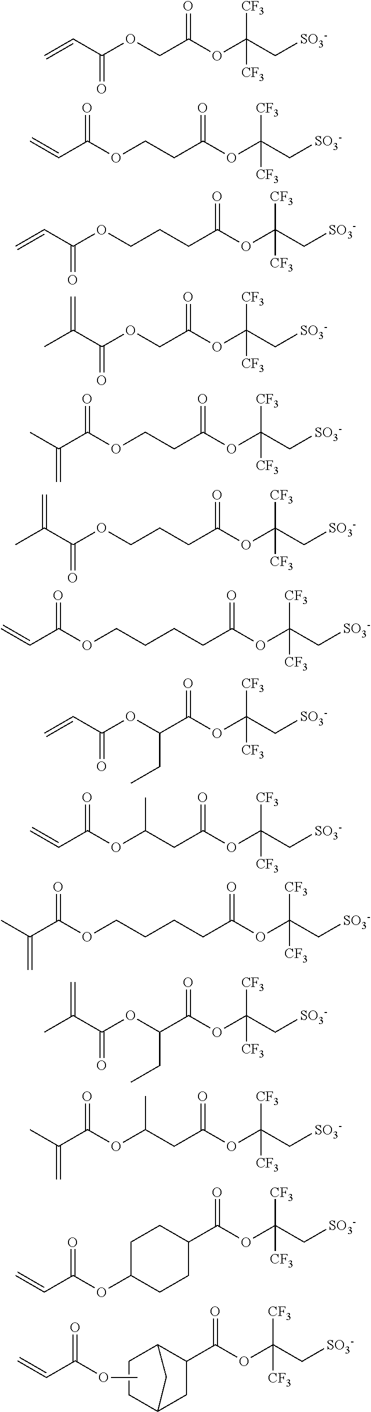

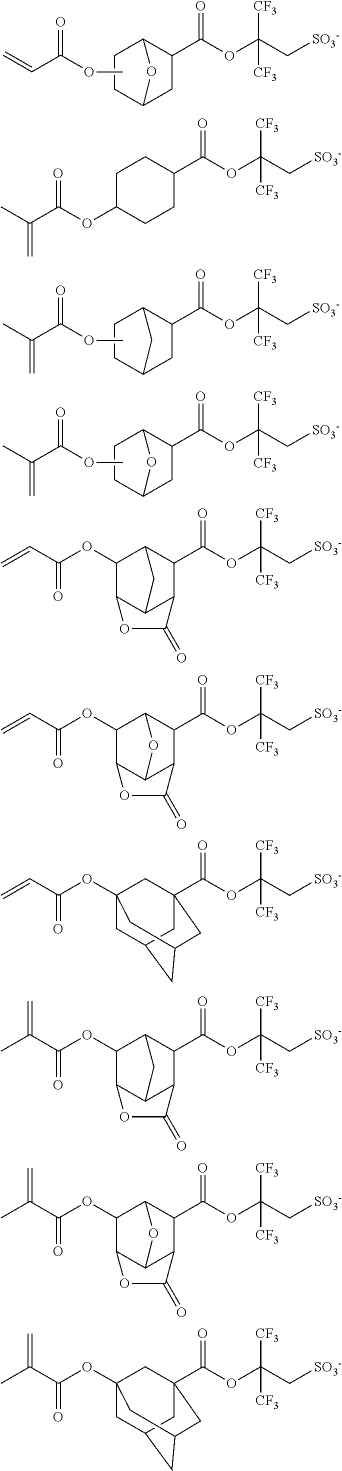

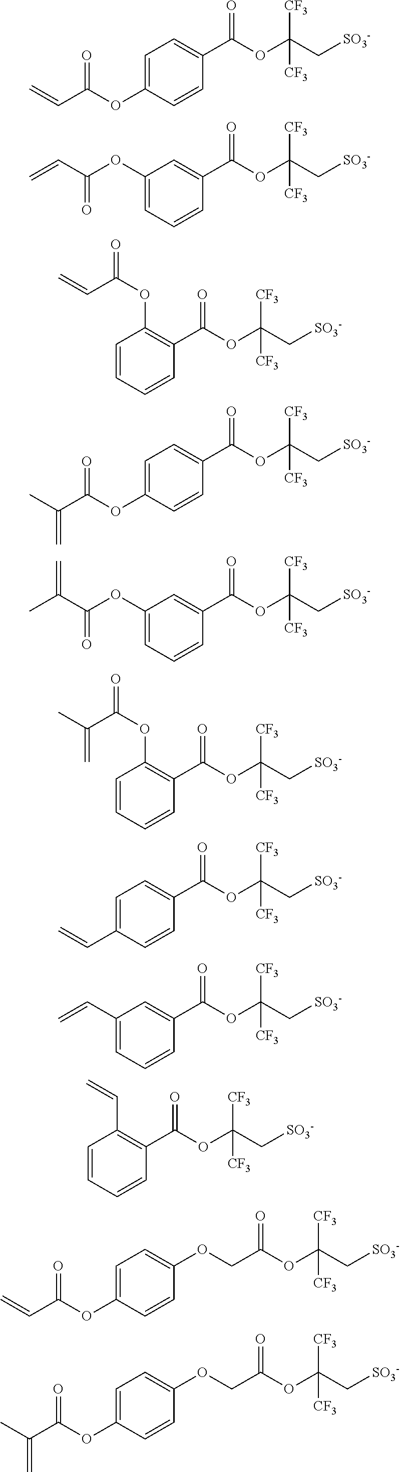

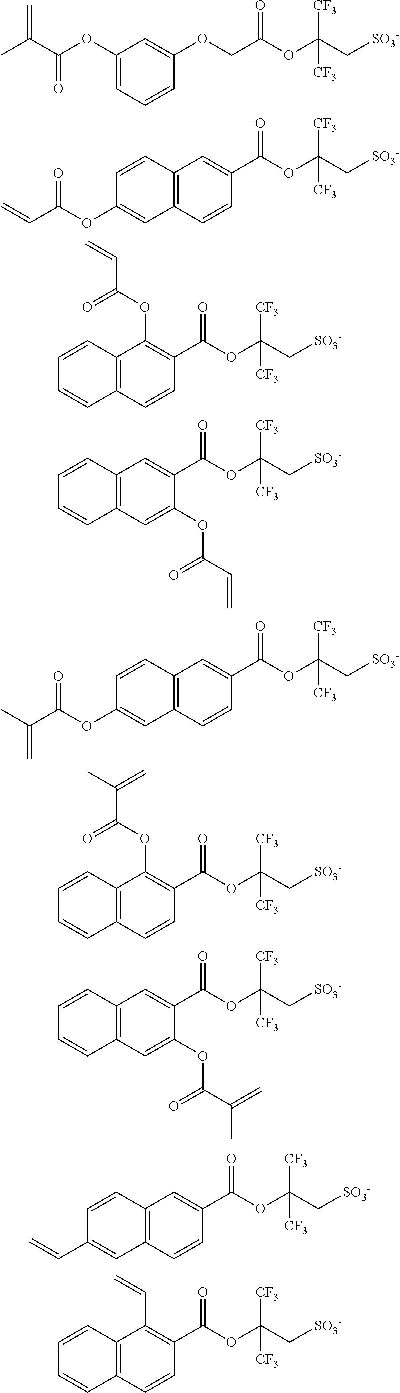

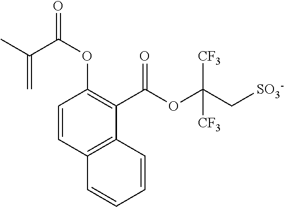

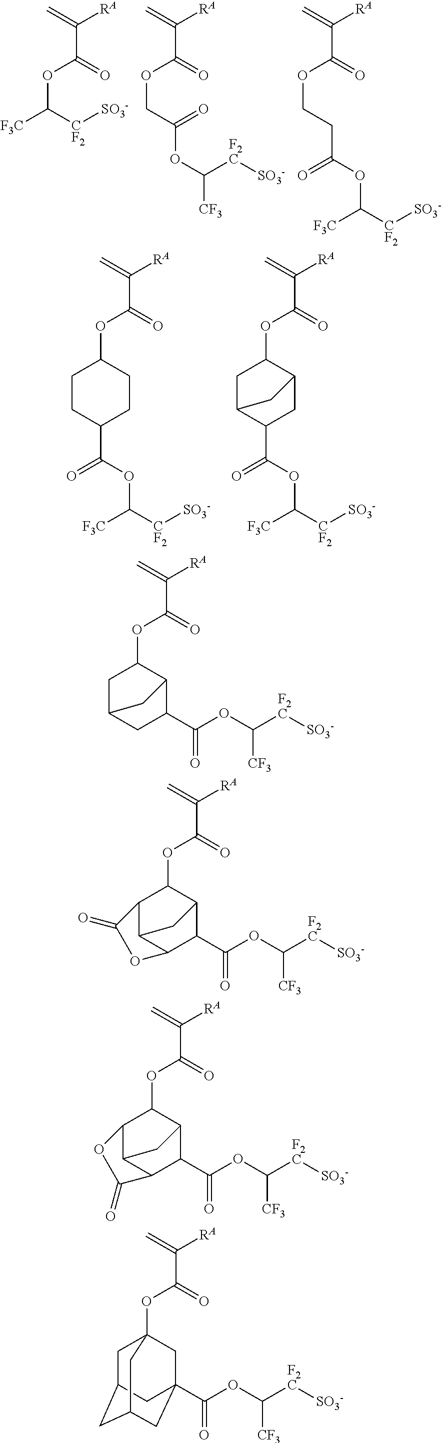

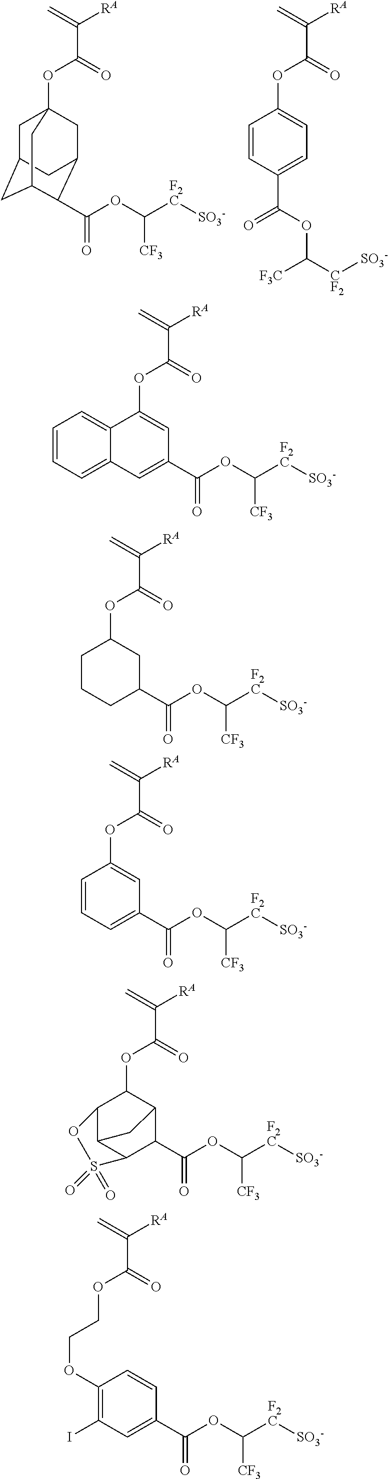

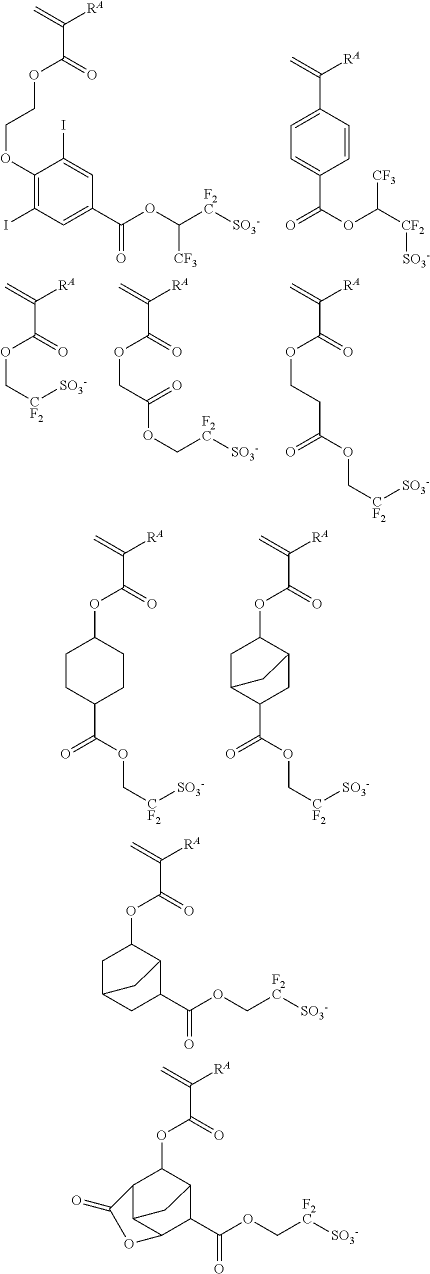

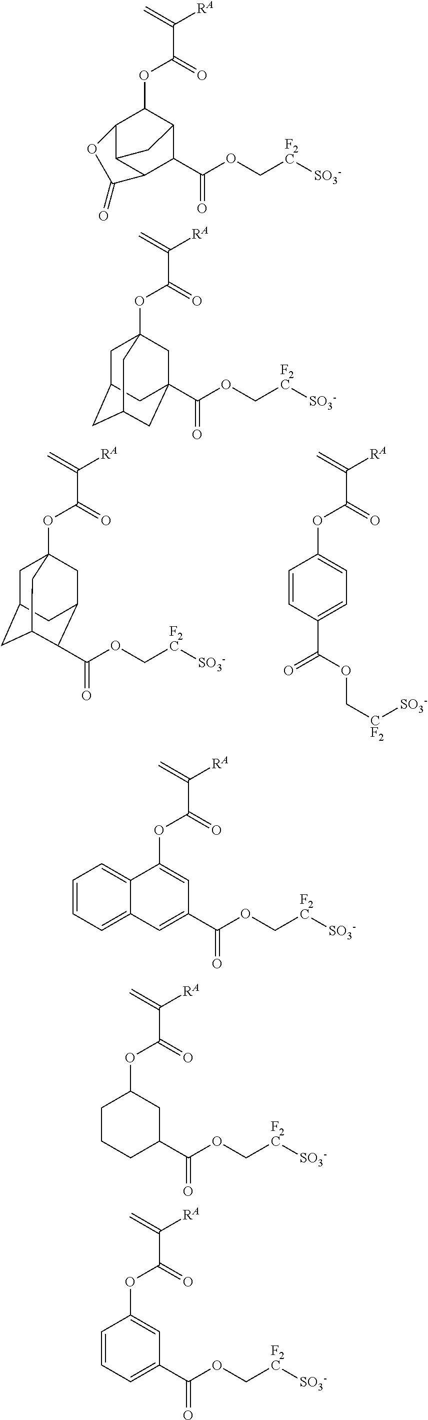

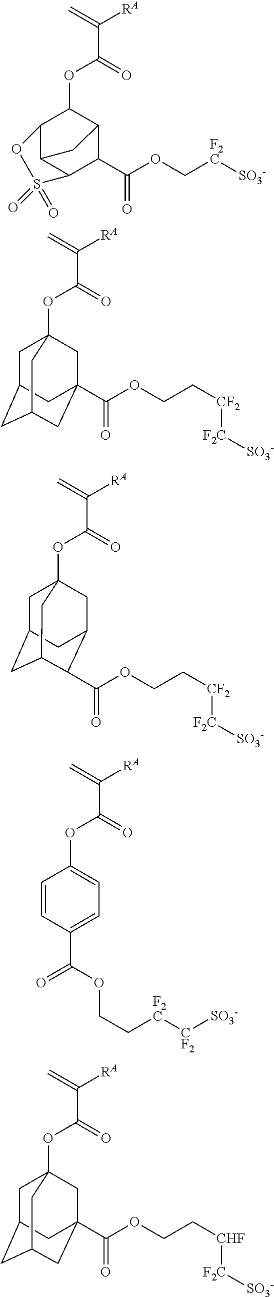

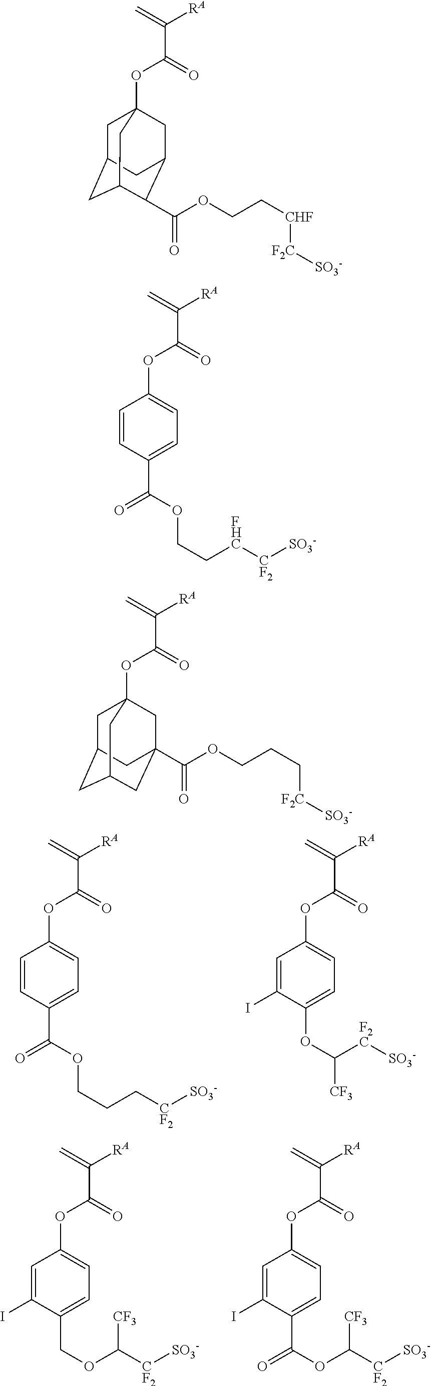

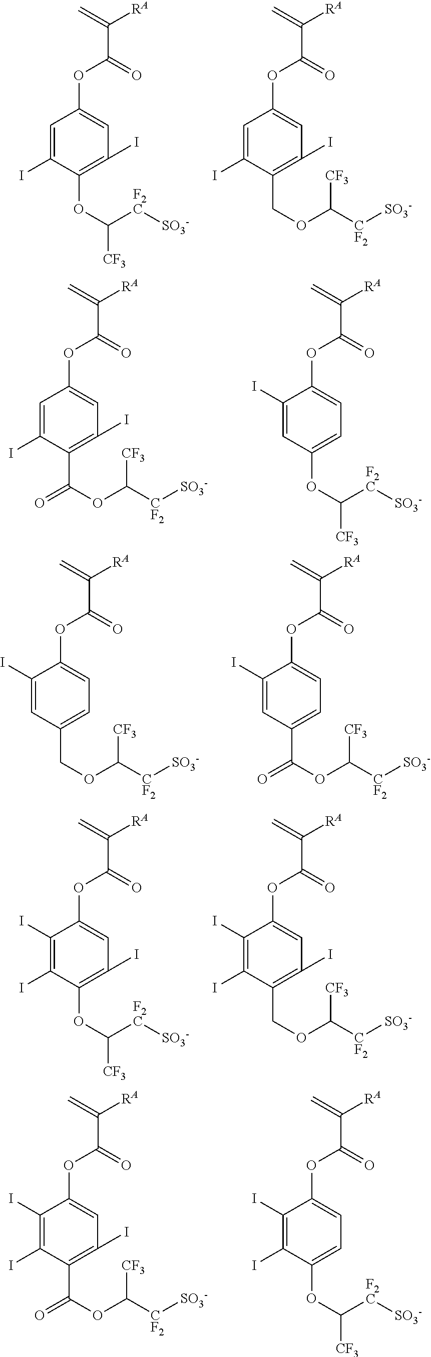

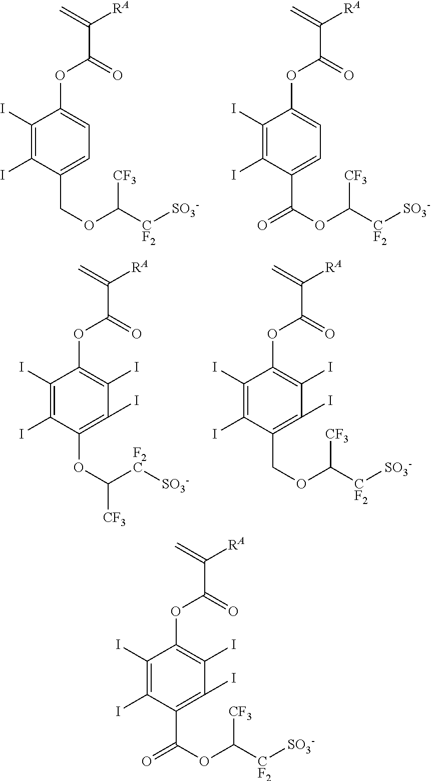

In the formula (c), R^{c2} to R^{c4} each independently represent a monovalent hydrocarbon group, in particular, a hydrocarbyl group, having 1 to 20 carbon atoms and optionally containing a heteroatom. The hydrocarbyl group having 1 to 20 carbon atoms, represented by R^{c2} to R^{c4}, may be saturated or unsaturated, and may be linear, branched, or cyclic. Specific examples of the hydrocarbyl group include: alkyl groups having 1 to 20 carbon atoms, such as a methyl group, an ethyl group, an n-propyl group, an isopropyl group, an n-butyl group, an isobutyl group, a sec-butyl group, a tert-butyl group, an n-pentyl group, an n-hexyl group, an n-octyl group, an n-nonyl group, an n-decyl group, an undecyl group, a dodecyl group, a tridecyl group, a tetradecyl group, a pentadecyl group, a heptadecyl group, an octadecyl group, a nonadecyl group, and an icosyl group; cyclic saturated hydrocarbyl groups having 3 to 20 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 20 carbon atoms, such as a vinyl group, a propenyl group, a butenyl group, and a hexenyl group; alkynyl groups having 2 to 20 carbon atoms, such as an ethynyl group, a propynyl group, and a butynyl group; cyclic unsaturated aliphatic hydrocarbyl groups having 3 to 20 carbon atoms, such as a cyclohexenyl group and a norbornenyl group; aryl groups having 6 to 20 carbon atoms, such as a phenyl group, a methylphenyl group, an ethylphenyl group, an n-propylphenyl group, an isopropylphenyl group, an n-butylphenyl group, an isobutylphenyl group, a sec-butylphenyl group, a tert-butylphenyl group, a naphthyl group, a methylnaphthyl group, an ethylnaphthyl group, an n-propylnaphthyl group, an isopropylnaphthyl group, an n-butylnaphthyl group, an isobutylnaphthyl group, a sec-butylnaphthyl group, and a tert-butylnaphthyl group; aralkyl groups having 7 to 20 carbon atoms, such as a benzyl group and a phenethyl group; groups which are combinations of these groups; etc. In addition, part or all of the hydrogen atoms of the hydrocarbyl groups may be substituted with a group containing a heteroatom, such as an oxygen atom, a sulfur atom, a nitrogen atom, and a halogen atom. Part of the —CH₂— of the hydrocarbyl groups may be substituted with a group containing a heteroatom, such as an oxygen atom, a sulfur atom, and a nitrogen atom, and the resulting hydrocarbyl groups may contain a hydroxy group, a fluorine atom, a chlorine atom, a bromine atom, an iodine atom, a cyano group, a carbonyl group, an ether bond, an ester bond, a sulfonic acid ester bond, a carbonate group, a lactone ring, a sultone ring, a carboxylic acid anhydride (—C(═O)—O—C(═O)—), a haloalkyl group, etc.

Furthermore, R^{c2} and R^{c3} may be bonded to each other to form a ring together with the sulfur atom bonded thereto. In this case, the ring preferably has a structure shown below.

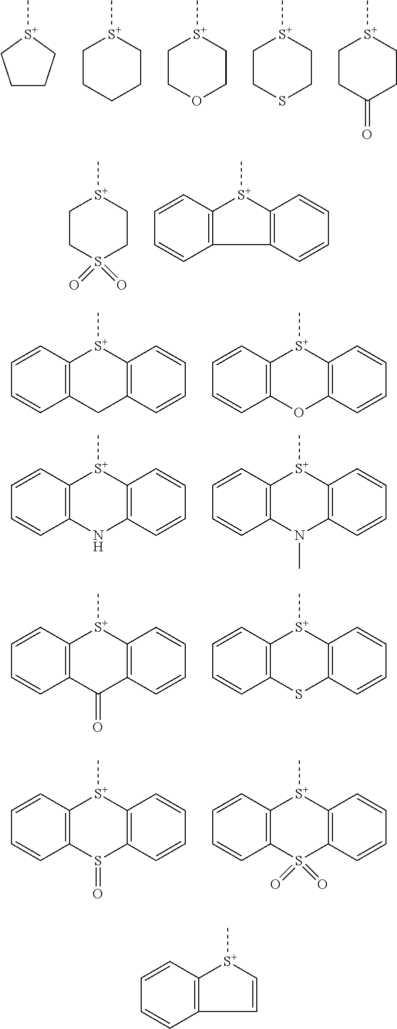

In the formulae, a broken line represents an attachment point to R^{c4}.

Examples of cations of monomers to give the repeating unit (c) include the following, but are not limited thereto.

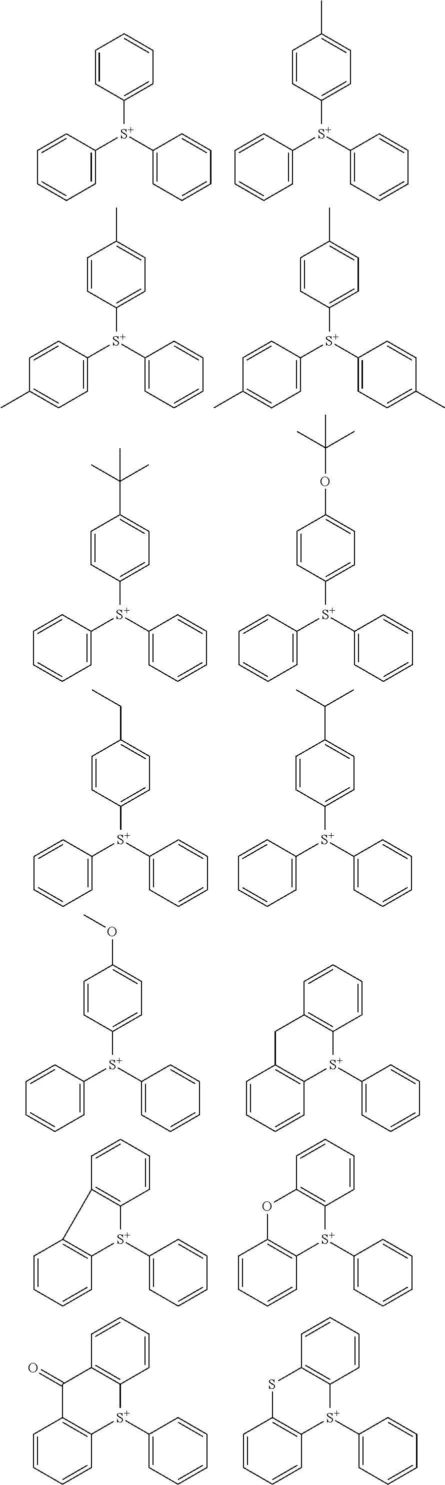

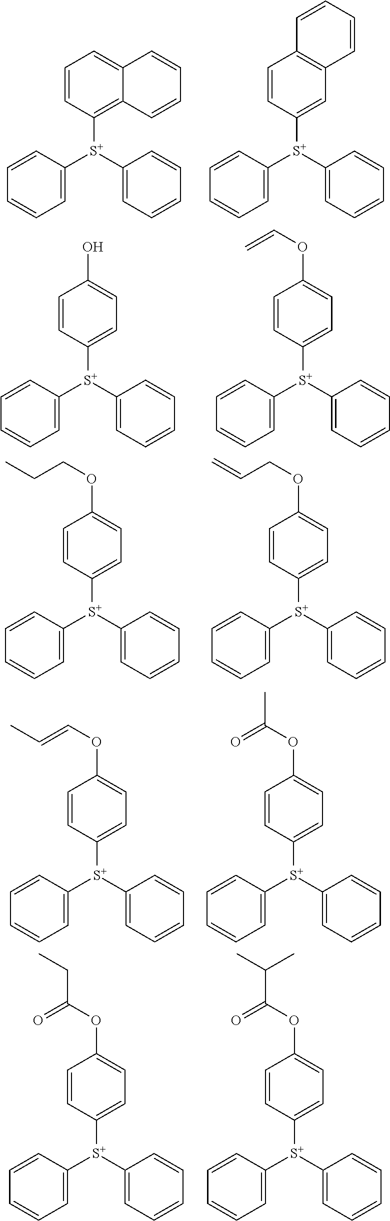

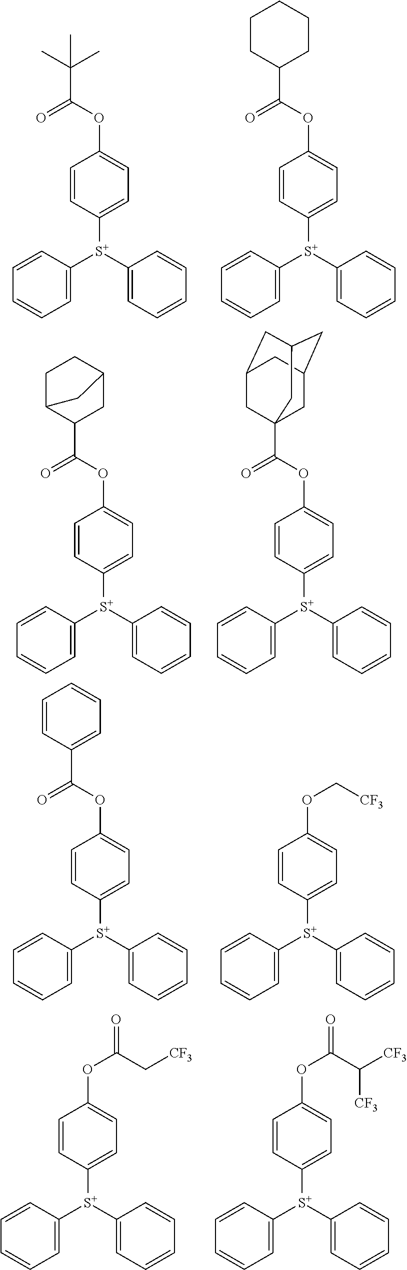

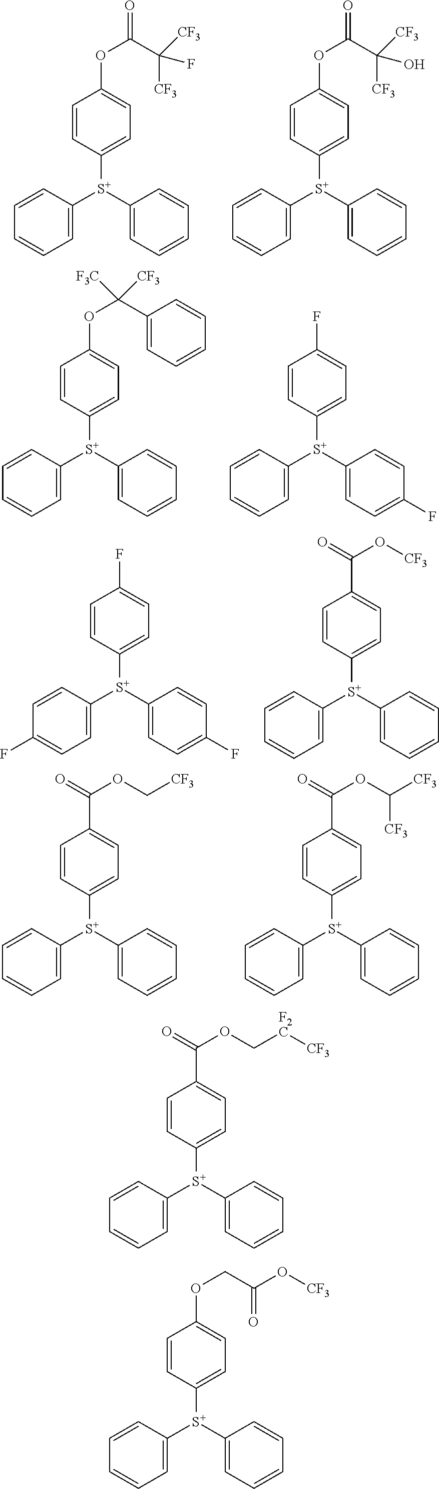

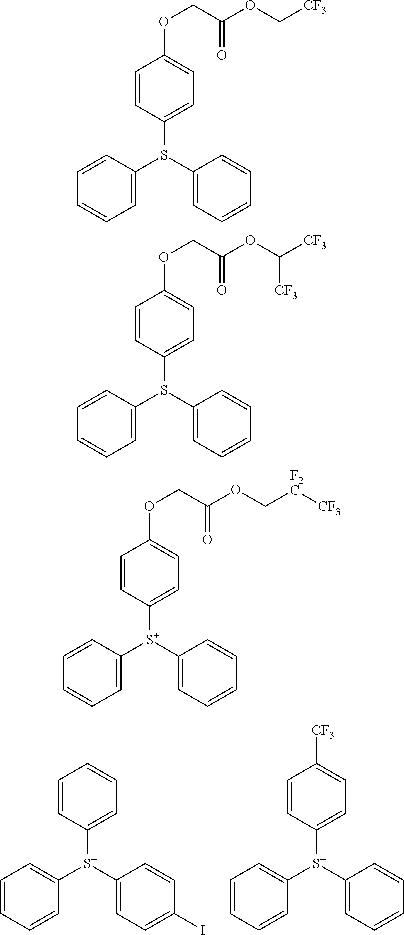

The repeating unit (B) is preferably contained at a percentage of 10 mol % or more and 70 mol % or less based on the total amount of the repeating units contained in the base polymer (P). Meanwhile, the repeating unit (C) is preferably contained at a percentage of 0 mol % or more and 20 mol % or less based on the total amount of the repeating units contained in the base polymer (P).

The base polymer may contain a repeating unit (hereinafter, also referred to as a repeating unit (D)) other than the repeating units (A) to (C). As the repeating unit (D), it is possible to use known repeating units used in base polymers of resist compositions, and specific examples thereof include (meth)acrylic acid ester units, (meth)acrylic acid units, etc. having a lactone structure or an adhesive group such as a hydroxy group other than a phenolic hydroxy group, a carboxy group, etc.

The base polymer may be synthesized, for example, by subjecting the monomers to give the repeating units described above to heat polymerization in an organic solvent to which a radical polymerization initiator has been added.

The base polymer has a polystyrene-based weight-average molecular weight (Mw) of preferably 1,000 to 500,000, more preferably 2,000 to 30,000, determined by gel permeation chromatography (GPC) using THF as an eluent. When the Mw is 1,000 or more, the resist material is provided with excellent heat resistance, and when 500,000 or less, alkali solubility does not decrease, and there is no risk that a trailing phenomenon becomes likely to occur after pattern formation.

Further, when the base polymer has a molecular weight distribution (Mw/Mn) of 1.0 to 2.0, low-molecular-weight and high-molecular-weight polymers are not present, and therefore, there are no risks of foreign matters being found on the pattern after the exposure or the pattern profile being degraded. The finer the pattern rule, the stronger the influences of Mw and Mw/Mn. Hence, in order to obtain a resist material suitably used for finer pattern dimensions, the base polymer preferably has a narrow dispersity Mw/Mn of 1.0 to 2.0, particularly preferably 1.0 to 1.5.

The amount of the base polymer (P) contained in the inventive resist material is not particularly limited, but can be 0.5 to 50 parts by mass, preferably 1 to 10 parts by mass based on 100 parts by mass of the resist material.

### [Photo-Acid Generator]

The inventive resist material may further contain an additive-type photo-acid generator. The acid that is generated from the photo-acid generator in the present invention is a strong acid having an acidity equivalent to that of the acid generated from the repeating unit (C) of the base polymer (P), acts on the acid-labile group or crosslinked structure of the repeating unit (B), and contributes to the improvement of dissolution contrast.

Examples of the acid generator include compounds that generate acids in response to actinic light or radiation (photo-acid generators). The photo-acid generator can be any photo-acid generator as long as the compound generates an acid upon high-energy beam irradiation. Preferably, the photo-acid generator generates a sulfonic acid, imide acid, or methide acid. Suitable photo-acid generators include sulfonium salt, iodonium salt, sulfonyldiazomethane, N-sulfonyloxyimide, oxime-O-sulfonate type acid generators, etc. Specific examples of the photo-acid generator include ones disclosed in paragraphs [0122] to [0142] of JP 2008-111103 A.

Examples of the anion moiety of the photo-acid generator include those having structures represented by the following formulae (2A) to (2D).

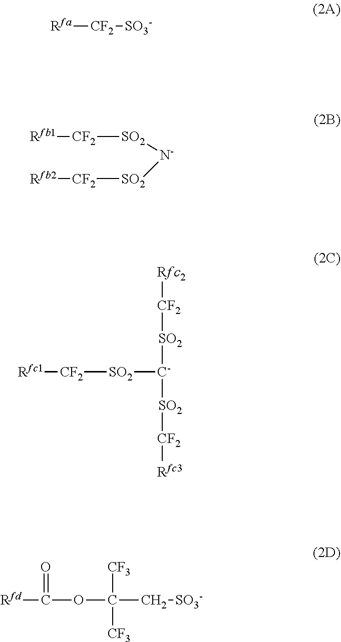

In the formula (2A), R^{fa} represents a fluorine atom or a hydrocarbyl group having 1 to 40 carbon atoms and optionally containing a heteroatom. The hydrocarbyl group may be saturated or unsaturated, and may be linear, branched, or cyclic. Specific examples thereof include groups given as a hydrocarbyl group represented by R¹ in the formula (2A′) described below.

As the anion represented by the formula (2A), an anion represented by the following formula (2A′) is preferable.

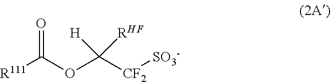

In the formula (2A′), R^{HF} represents a hydrogen atom or a trifluoromethyl group, preferably a trifluoromethyl group. R¹¹¹ represents a hydrocarbyl group having 1 to 38 carbon atoms and optionally containing a heteroatom. The heteroatom is preferably an oxygen atom, a nitrogen atom, a sulfur atom, a halogen atom, or the like, more preferably an oxygen atom. The hydrocarbyl group particularly preferably has 6 to 30 carbon atoms from the viewpoint of achieving high resolution in fine pattern formation.

The hydrocarbyl group represented by R¹¹¹ may be saturated or unsaturated, and may be linear, branched, or cyclic. Specific examples thereof include alkyl groups having 1 to 38 carbon atoms, such as a methyl group, an ethyl group, an n-propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group; cyclic saturated hydrocarbyl groups having 3 to 38 carbon atoms, such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group; unsaturated aliphatic hydrocarbyl groups having 2 to 38 carbon atoms, such as an allyl group and a 3-cyclohexenyl group; aryl groups having 6 to 38 carbon atoms, such as a phenyl group, a 1-naphthyl group, and a 2-naphthyl group; aralkyl groups having 7 to 38 carbon atoms, such as a benzyl group and a diphenylmethyl group; groups which are combinations of these groups; etc.

Furthermore, part or all of the hydrogen atoms of these groups may be substituted with a group containing a heteroatom, such as an oxygen atom, a sulfur atom, a nitrogen atom, or a halogen atom, and part of the —CH₂— of these groups may be substituted with a group containing a heteroatom such as an oxygen atom, a sulfur atom, or a nitrogen atom. The resulting hydrocarbyl group may contain a hydroxy group, a fluorine atom, a chlorine atom, a bromine atom, an iodine atom, a cyano group, a nitro group, a carbonyl group, an ether bond, an ester bond, a sulfonic acid ester bond, a carbonate bond, a lactone ring, a sultone ring, a carboxylic anhydride, a haloalkyl group, etc. Examples of the hydrocarbyl group containing a heteroatom include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, a 3-oxocyclohexyl group, etc.

The synthesis of the sulfonium salt containing the anion shown by the formula (2A′) is described in detail in JP 2007-145797 A, JP 2008-106045 A, JP 2009-7327 A, JP 2009-258695 A, etc. In addition, sulfonium salts disclosed in JP 2010-215608 A, JP 2012-41320 A, JP 2012-106986 A, JP 2012-153644 A, etc. are also suitably used.

Examples of the anion represented by the formula (2A) include those given as examples of the anion represented by a formula (1A) in JP 2018-197853 A.

In the formula (2B), R^{fb1} and R^{fb2} each independently represent a fluorine atom or a hydrocarbyl group having 1 to 40 carbon atoms and optionally containing a heteroatom. The hydrocarbyl group may be saturated or unsaturated, and may be linear, branched, or cyclic. Specific examples thereof include those given as examples of the hydrocarbyl group represented by the R¹¹¹ in the formula (2A′). R^{fb1} and R^{fb2} are preferably a fluorine atom or a linear fluorinated alkyl group having 1 to 4 carbon atoms. Alternatively, R^{fb1} and R^{fb2} may bond with each other to form a ring together with the group (—CF₂—SO₂—N—SO₂—CF₂—) bonded therewith. In this event, the group obtained by R^{fb1} and R^{fb2} being bonded to each other is preferably a fluorinated ethylene group or a fluorinated propylene group.

In the formula (2C), R^{fc1}, R^{fc2}, and R^{fc3} each independently represent a fluorine atom or a hydrocarbyl group having 1 to 40 carbon atoms and optionally containing a heteroatom. The hydrocarbyl group may be saturated or unsaturated, and may be linear, branched, or cyclic. Specific examples thereof include those given as examples of the hydrocarbyl group represented by the R¹¹¹ in the formula (2A′). R^{fc1}, R^{fc2}, and R^{fc3} are preferably a fluorine atom or a linear fluorinated alkyl group having 1 to 4 carbon atoms. Alternatively, R^{fc1} and R^{fc2} may bond with each other to form a ring together with the group (—CF₂—SO₂—C—SO₂—CF₂—) bonded therewith. In this event, the group obtained by R^{fc1} and R^{fc2} being bonded with each other is preferably a fluorinated ethylene group or a fluorinated propylene group.

In the formula (2D), R^{fd} represents a hydrocarbyl group having 1 to 40 carbon atoms and optionally containing a heteroatom. The hydrocarbyl group may be saturated or unsaturated, and may be linear, branched, or cyclic. Specific examples thereof include those given as examples of the hydrocarbyl group represented by the R¹¹¹ in the formula (2A′).

The synthesis of the sulfonium salt containing the anion shown by the formula (2D) is described in detail in JP 2010-215608 A and JP 2014-133723 A.

Examples of the anion represented by the formula (2D) include those given as examples of the anion represented by a formula (1 D) in JP 2018-197853 A.

Note that the photo-acid generator containing the anion shown by the formula (1D) does not have a fluorine atom at a position of the sulfo group, but has two trifluoromethyl groups at p position, thereby providing sufficient acidity to cut the acid-labile group in the base polymer. Thus, this photo-acid generator is utilizable.

Examples of the cation moiety of the photo-acid generator include those given as examples of the sulfonium cation in the repeating unit (C).

The amount of the photo-acid generator to be contained is not particularly limited. When the photo-acid generator is contained, the amount is, for example, preferably 1 to 50 parts by mass, more preferably 5 to 30 parts by mass based on 80 parts by mass of the base polymer (P).

### [Crosslinking Agent]

The crosslinking agent in the present invention undergoes an addition reaction with the carboxy group or the hydroxy group contained in the repeating unit (A) of the base polymer (P). In a process of prebaking on a substrate, the molecular weight of the base polymer is considerably increased by the crosslinking of the base polymer, and the diffusion of the acid and the dissolution to the developer are suppressed. Furthermore, the crosslinked structure is decomposed by the strong acid component generated by exposure and the molecular weight is reduced only in exposed portions, and thus, the contrast with unexposed portions can be enhanced.

The crosslinking agent has a structure represented by the following formula (1).

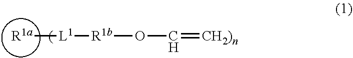

In the formula, R^{1a} represents an organic group optionally having a substituent; L¹ represents a linking group selected from a single bond, an ester bond, and an ether bond; R^{1b} represents a single bond or a divalent organic group; and “n” represents an integer of 2 to 4.

Regarding the crosslinking agent, the R^{1a} in the formula (1) preferably contains an aromatic hydrocarbon group.

Regarding the crosslinking agent, in the formula (1), “n” is preferably an integer of 3 or more. L¹ preferably contains an ether bond. R^{1b} preferably contains an aliphatic hydrocarbon group.

Examples of the crosslinking agent represented by the formula (1) include the following, but are not limited thereto.

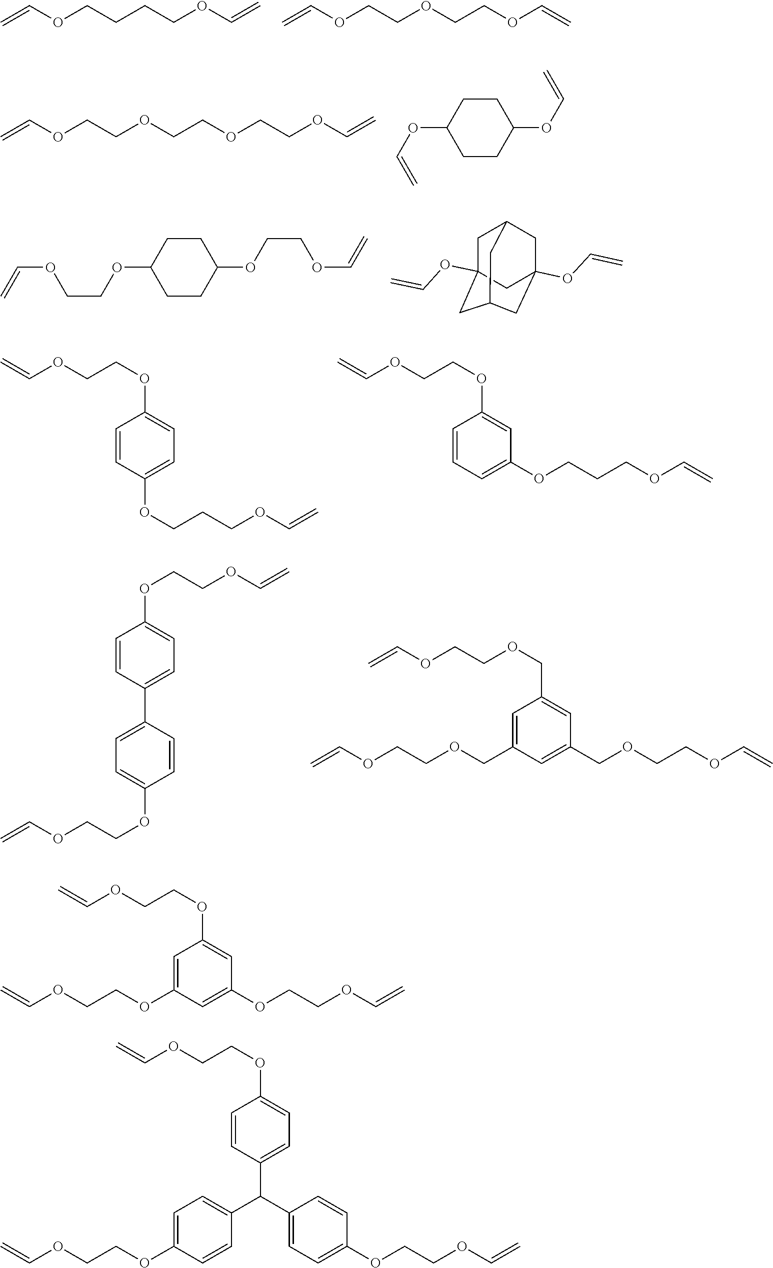

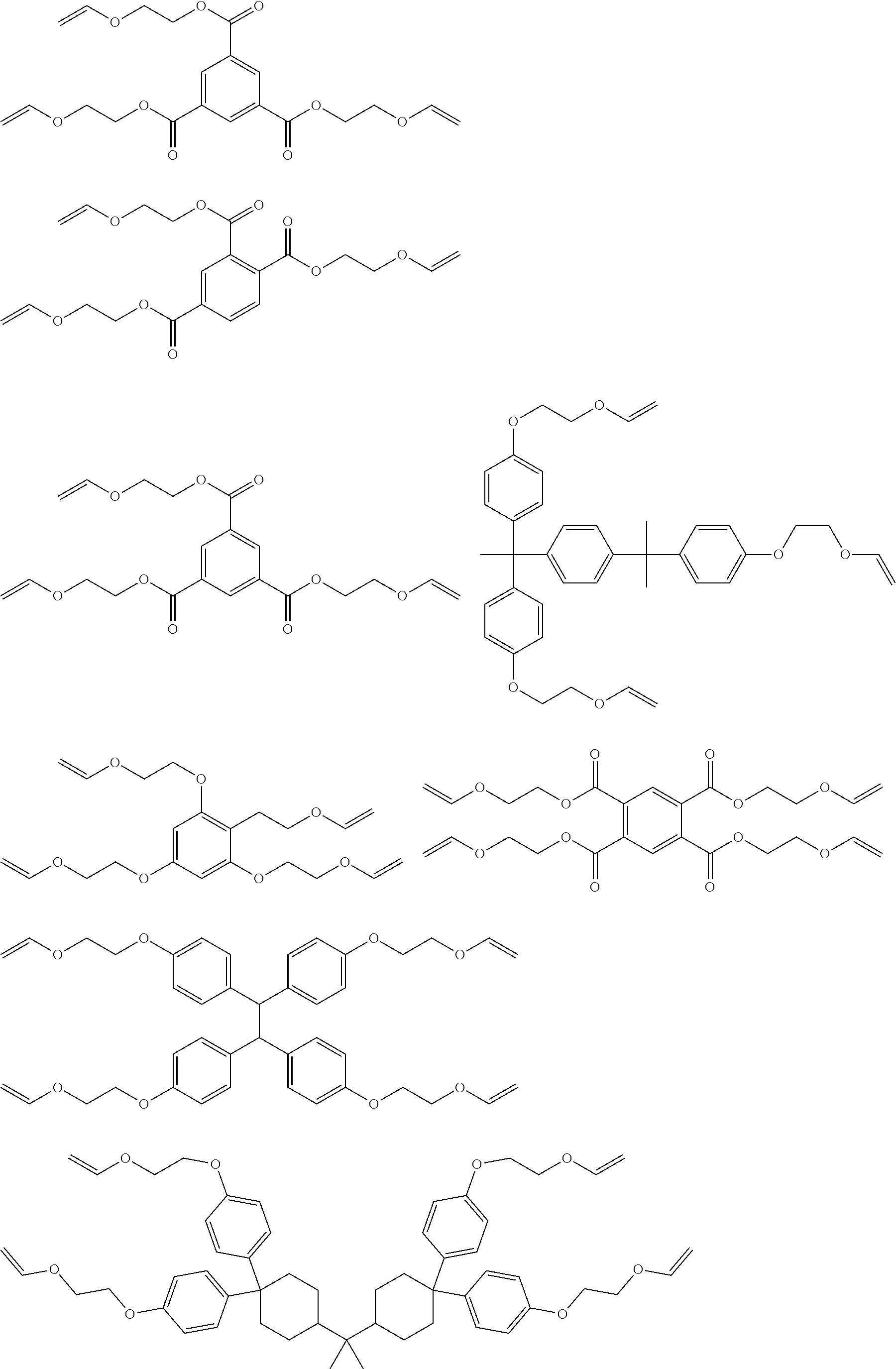

The amount of the crosslinking agent to be contained is not particularly limited, and for example, the amount is preferably 1 to 30 parts by mass, more preferably 3 to 20 parts by mass based on 80 parts by mass of the base polymer (P).

### [Photodecomposable Quencher]

The photodecomposable quencher in the present invention is an organic salt consisting of an organic weak acid anion that generates an acid weaker than that of the repeating unit (C) in the base polymer (P) and a sulfonium cation. The weak acid anion undergoes salt exchange with the strong acid generated by exposure, and forms weak acid- and strong acid-sulfonium cation salts. By replacing the strong acid generated in the exposed portions with a weak acid in this manner, the modification of the base polymer due to an acid is suppressed. Meanwhile, in a region where the exposure dose is sufficiently large, the sulfonium cations after the salt exchange are also decomposed and generate a strong acid, and the dissolution rate of the resist film in a developer changes, so that a pattern can be formed.

The photodecomposable quencher has a structure represented by the following formula (2).

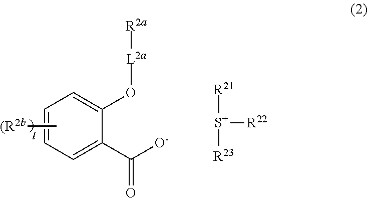

In the formula, R²¹ to R²³ each independently represent a monovalent hydrocarbon group having 1 to 20 carbon atoms and optionally containing a heteroatom, any two of R²¹, R²², and R²³ optionally being bonded to each other to form a ring together with the sulfur atom bonded thereto, “I” represents an integer of 0 to 4, R^{2b} represents a halogen atom, a hydroxy group, a nitro group, a hydrocarbon group having 1 to 20 carbon atoms and optionally having a substituent, an alkoxy group having 1 to 18 carbon atoms and optionally having a substituent, an amino group optionally having a substituent, or a phenyl group optionally having a substituent, when “I” is 2 or more, the R^{2b}s optionally being different from each other, L^{2a} represents a single bond, an ester bond, or a divalent linking group having 1 to 8 carbon atoms, and R^{2a} represents a hydrogen atom or a hydrocarbon group having 1 to 18 carbon atoms and optionally having a substituent, R^{2a} and R^{2b} optionally being bonded to each other to form a ring together with the carbon atoms bonded thereto.

When the photodecomposable quencher has the structure represented by the formula (2), it is possible to suppress the diffusion of the strong acid that is generated in exposed portions. Meanwhile, the generation of the weak acid from the thermal acid generator that occurs in the process of baking the resist film and the crosslinking reaction between the crosslinking agent and the polymer with the weak acid as a catalyst are not inhibited, and therefore, the molecular weight can be increased efficiently.

Furthermore, the photodecomposable quencher preferably has an iodine atom.

In addition, when the photodecomposable quencher has a hydroxy group, the base polymer and the quencher component are bonded to each other via the crosslinking agent, and therefore, the diffusion of the quencher component can be suppressed.

Examples of the structure of the anion moiety of the quencher include the following, but are not limited thereto.

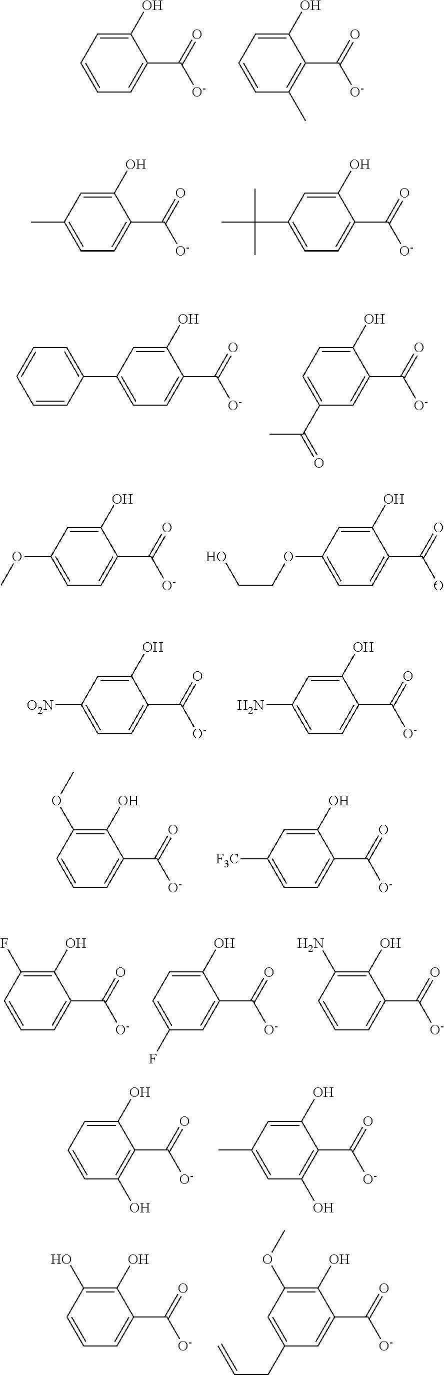

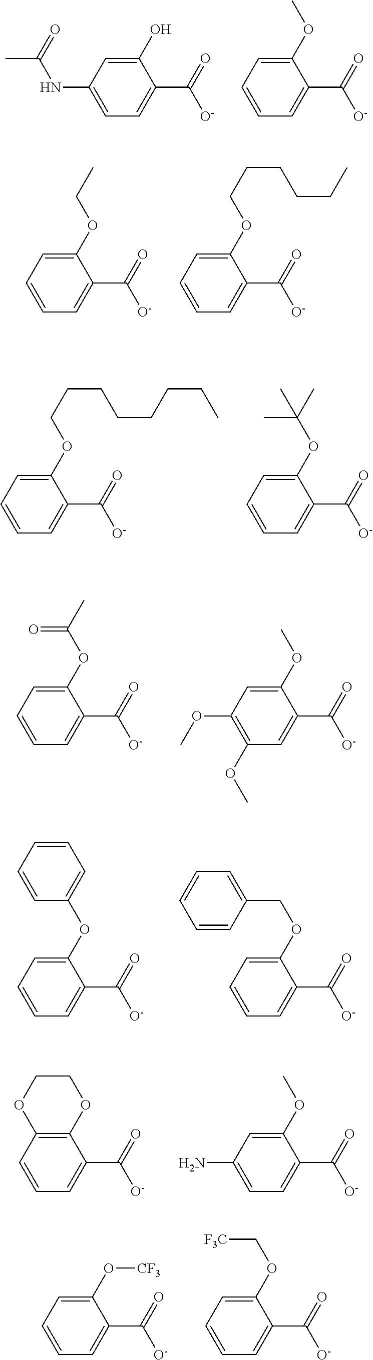

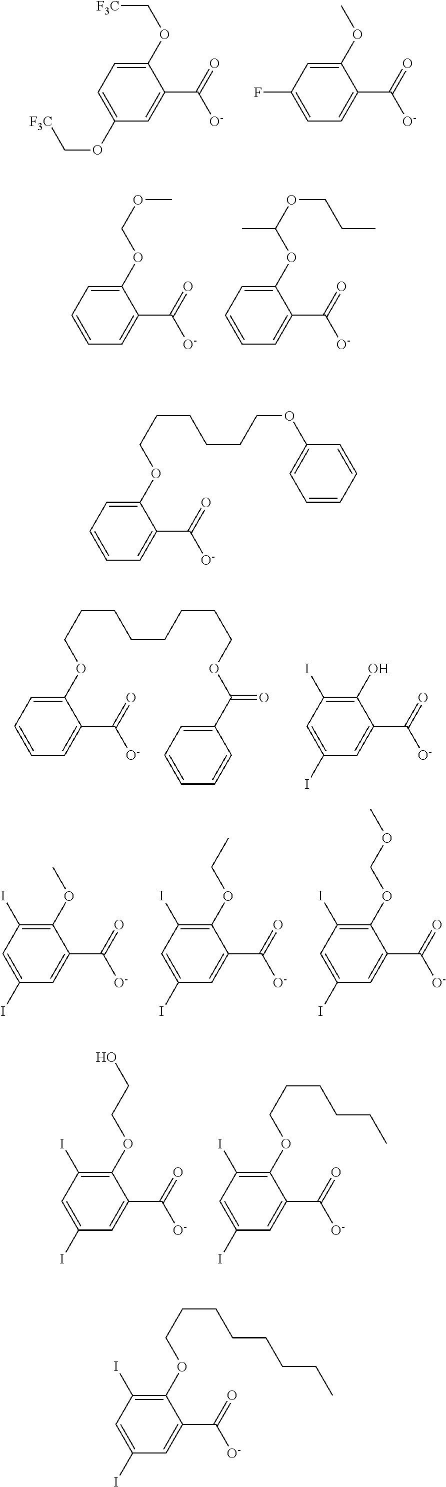

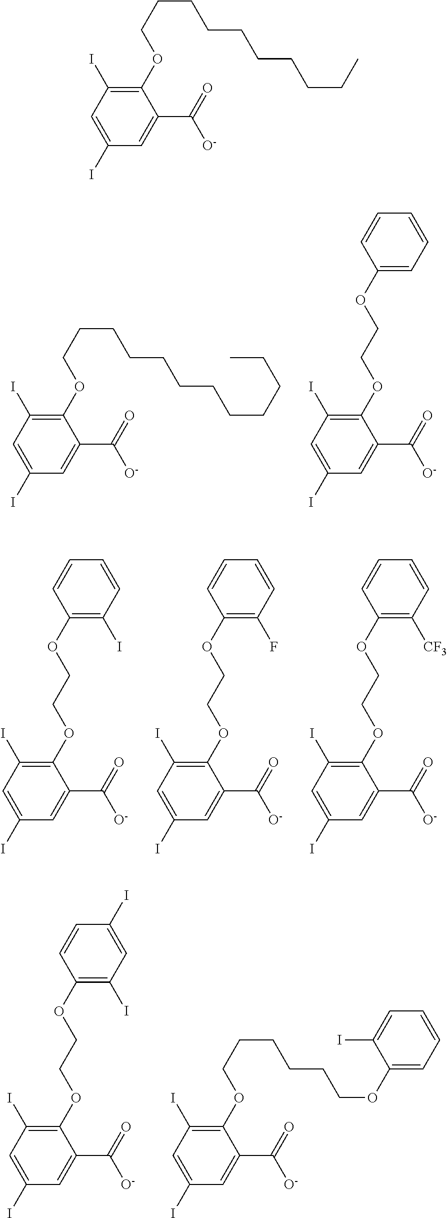

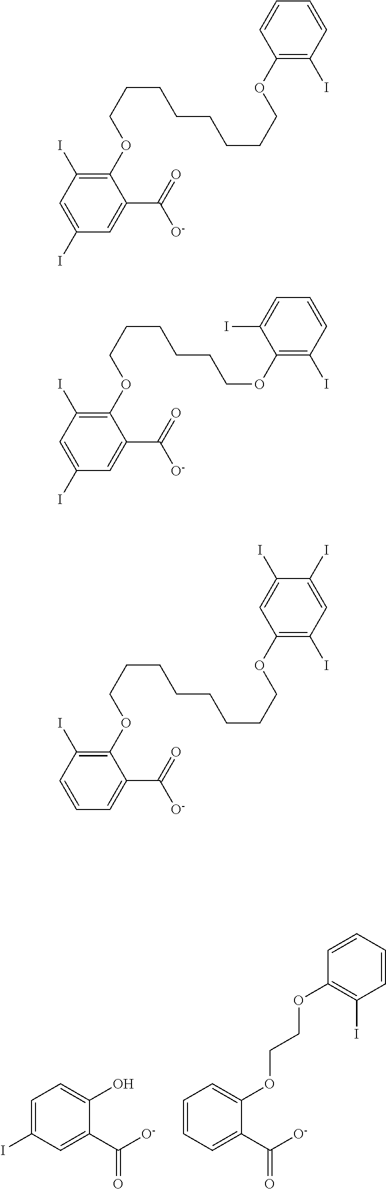 [SMILES: O=C([O-])c1cc(I)cc(I)c1OCCCCCCCCOc1ccccc1I ; O=C([O-])c1cc(I)cc(I)c1OCCCCCCOc1c(I)cccc1I ; O=C([O-])c1cccc(I)c1OCCCCCCCCOc1cc(I)c(I)cc1I ; O=C([O-])c1cc(I)ccc1O ; O=C([O-])c1ccccc1OCCOc1ccccc1I]

Examples of the cation moiety of the photodecomposable quencher include those given as examples of the sulfonium cation in the repeating unit (C).

The amount of the photodecomposable quencher to be contained is not particularly limited, and for example, the amount is preferably 1 to 30 parts by mass, more preferably 5 to 25 parts by mass based on 80 parts by mass of the base polymer (P).

### [Thermal Acid Generator]

The inventive resist material contains a thermal acid generator in order to promote the crosslinking reaction on a substrate. The acid generated from the thermal acid generator has a weaker acidity than the acid generated from the above-described photo-acid generator, and therefore, does not cause the decomposition of the crosslinked structure or the decomposition of the acid-labile group.

As the thermal acid generator, an onium salt consisting of an organic weak acid anion and an ammonium cation or an iodonium cation is suitably used.

Examples of the anion moiety of the thermal acid generator include those having a structure represented by one of the following formulae (4A) to (4C).

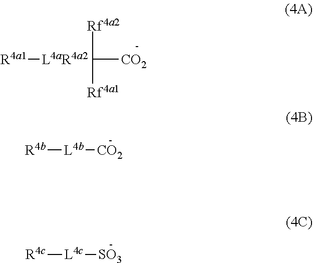

In the formula (4A), Rf^{4a1} and Rf^{4a2} each independently represent a hydrogen atom, a fluorine atom, or a trifluoromethyl group. R^{4a1} represents an organic group optionally having a substituent, and preferably contains an iodine atom. L^{4a} represents a linking group selected from a single bond, an ester bond, and an ether bond. R^{4a2} represents a divalent organic group optionally having a substituent.

In the formula (4B), L^{4b} represents a linking group selected from a single bond, an ester bond, and an ether bond, preferably a single bond. R^{4b} represents an organic group optionally having a substituent, preferably an aromatic hydrocarbon group having an iodine atom.

In the formula (4C), L^{4c} represents a linking group selected from a single bond, an ester bond, and an ether bond. R^{4c} represents an organic group optionally having a substituent, preferably an aliphatic hydrocarbon group.

The thermal acid generator preferably has a structure represented by the following formula (4).

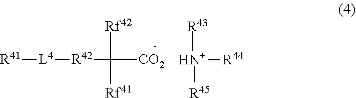

In the formula, R⁴¹ represents an organic group optionally having an iodine atom. The organic group may have a hydroxy group, a trifluoromethyl group, a different halogen atom, a nitro group, an amide group, or an alkoxy group. L⁴ represents a linking group selected from a single bond, an ester bond, and an ether bond. R⁴² represents a divalent organic group. Rf⁴¹ and Rf⁴² each independently represent a hydrogen atom, a fluorine atom, or a trifluoromethyl group. R⁴³ to R⁴⁵ each represent an alkyl group having 1 or 2 carbon atoms.

Examples of the thermal acid generator include the following, but are not limited thereto.

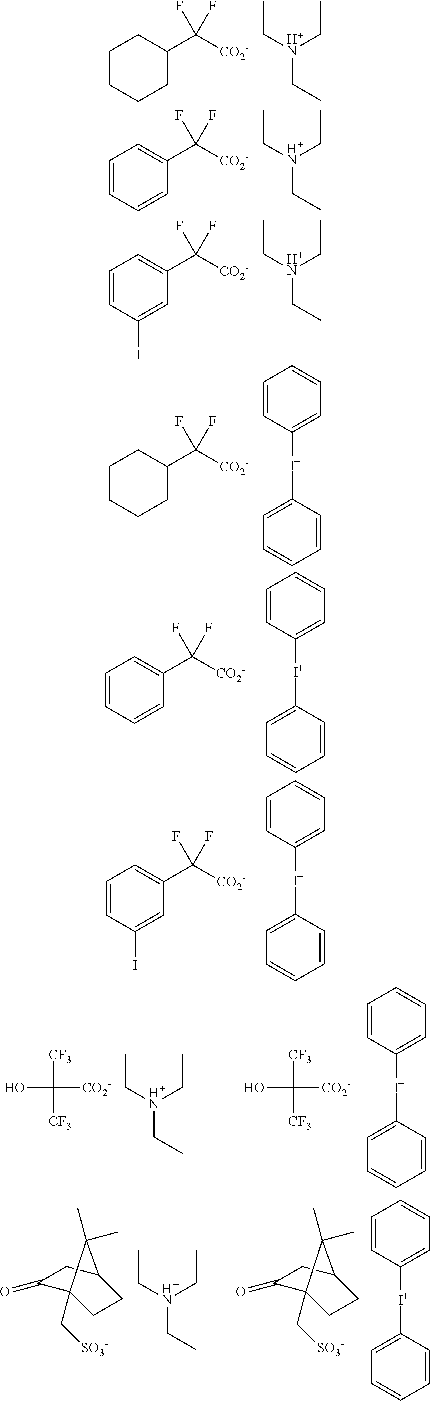

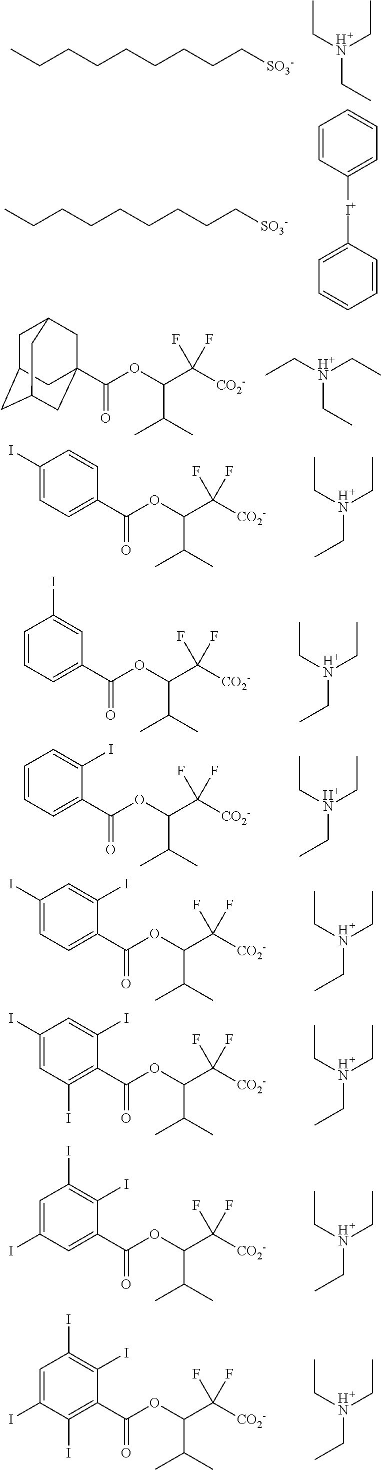

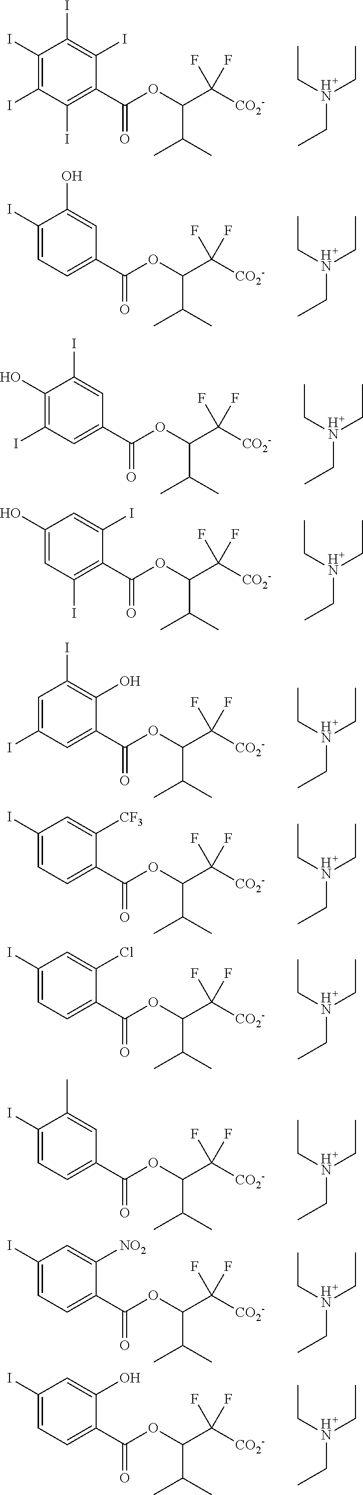

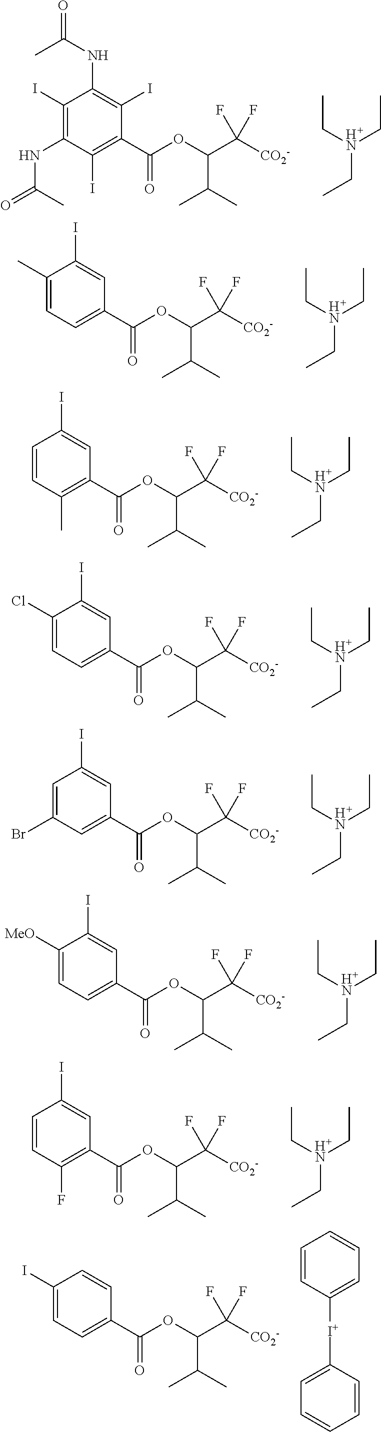

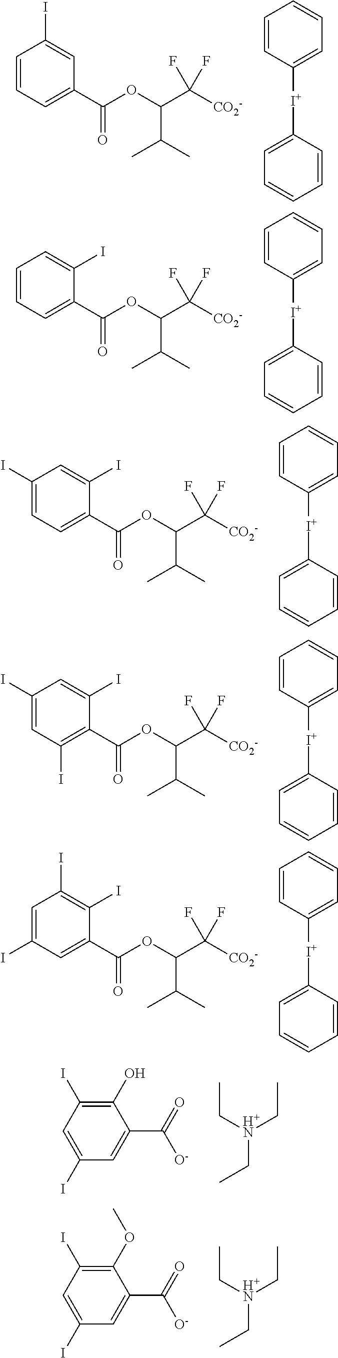

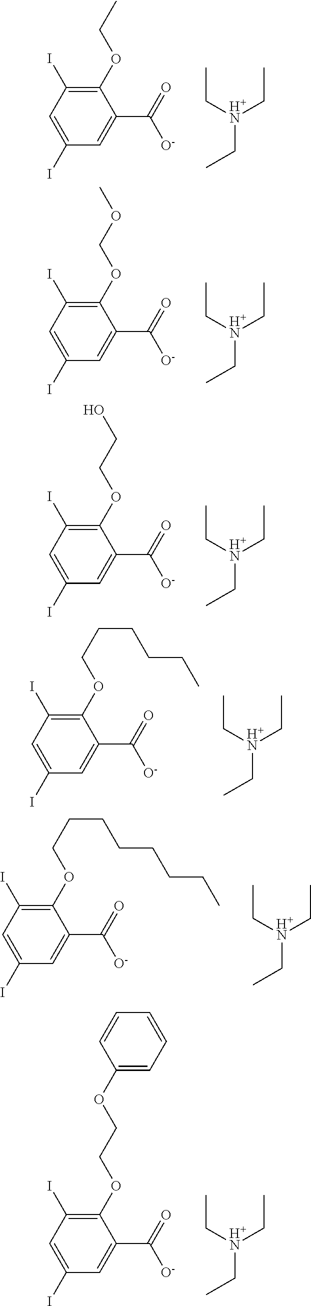

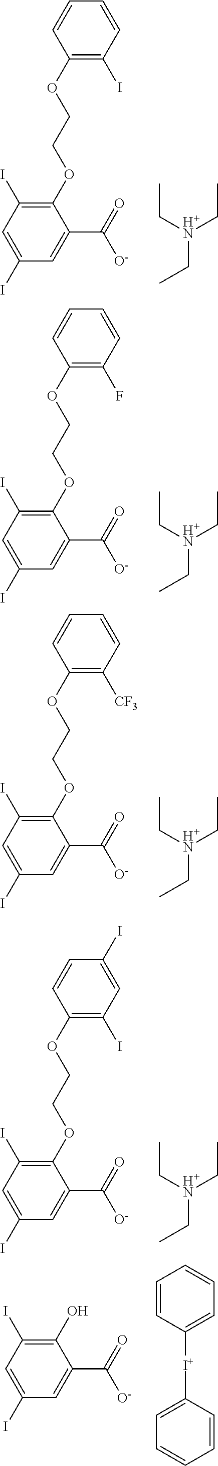

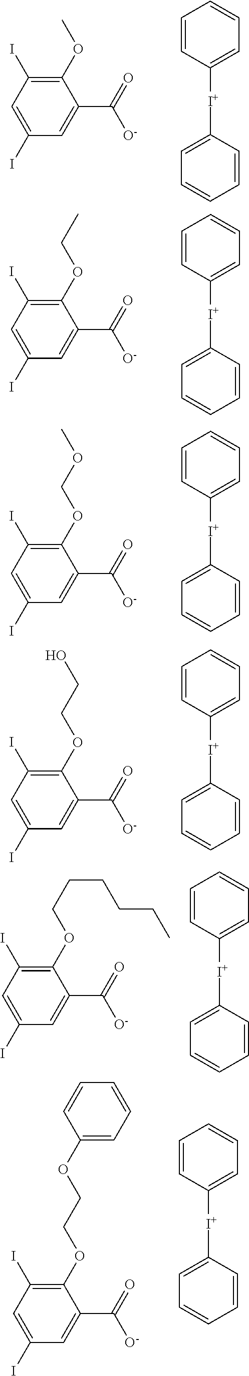

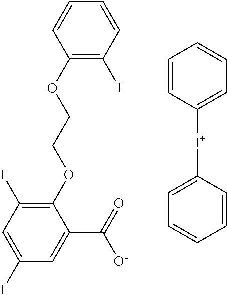 [SMILES: O=C([O-])c1cc(I)cc(I)c1OCCOc1ccccc1I ; c1ccc([I+]c2ccccc2)cc1]

The amount of the thermal acid generator to be contained is not particularly limited, but for example, is preferably 0.1 to 10 parts by mass, more preferably 0.5 to 5 parts by mass based on 80 parts by mass of the base polymer (P).

### [Organic Solvent]

The inventive resist material contains an organic solvent, and is not particularly limited as long as the organic solvent is capable of dissolving the components contained in the inventive resist material. Examples of the organic solvent include ones disclosed in paragraphs [0144] and [0145] of JP 2008-111103 A: ketones, such as cyclohexanone, cyclopentanone, methyl-2-n-pentyl ketone, and 2-heptanone; alcohols, such as 3-methoxybutanol, 3-methyl-3-methoxybutanol, 1-methoxy-2-propanol, 1-ethoxy-2-propanol, and diacetone alcohol; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones, such as γ-butyrolactone; etc.

When the inventive resist material contains an organic solvent, the contained amount is preferably 100 to 10000 parts by mass, more preferably 200 to 8000 parts by mass based on 80 parts by mass of the base polymer (P). One kind of the organic solvent may be used, or two or more kinds thereof may be used in mixture.

### [Surfactant]

The inventive resist material may further contain a surfactant. Examples of the surfactant include ones disclosed in paragraphs [0165] and [0166] of JP 2008-111103 A. Adding a surfactant can further enhance or control the coatability of the resist material. When the inventive resist material contains a surfactant, the contained amount is preferably 0.0001 to 10 parts by mass based on 80 parts by mass of the base polymer (P). One kind of the surfactant may be used, or two or more kinds thereof may be used in combination.

### [Patterning Process]

When the inventive resist material is used for manufacturing various integrated circuits, known lithography techniques are applicable. Examples of patterning processes include a method including the steps of:
(i) forming a resist film on a substrate by using the above-described resist material;
(ii) exposing the resist film to a high-energy beam; and
(iii) developing the exposed resist film by using a developer.
   [Step (i)]

The inventive resist material is applied onto a substrate (such as Si, SiO₂, SiN, SiON, TiN, WSi, BPSG, SOG, and organic antireflective film) for manufacturing an integrated circuit or a substrate (such as Cr, CrO, CrON, MoSi₂, and SiO₂) for manufacturing a mask circuit by an appropriate coating process, such as spin coating, roll coating, flow coating, dip coating, spray coating, or doctor coating, so that the coating film can have a thickness of 0.01 to 2 μm. The coating film is prebaked on a hot plate for 30 seconds to 20 minutes to form a resist film.

In the step (i), the prebaking temperature (baking temperature) is preferably 130° C. or higher. When the temperature is 130° C. or higher, a weak acid is generated from the thermal acid generator, and the crosslinking reaction progresses efficiently with the weak acid as a catalyst.

[Step (ii)]

Then, the resist film is exposed using a high-energy beam. Examples of the high-energy beam include ultraviolet ray, deep ultraviolet ray, EB, EUV having a wavelength of 3 to 15 nm, X-ray, soft X-ray, excimer laser beam, γ-ray, synchrotron radiation, etc. When ultraviolet ray, deep ultraviolet ray, EUV, X-ray, soft X-ray, excimer laser beam, γ-ray, synchrotron radiation, or the like is employed as the high-energy beam, the irradiation is performed directly or using a mask for forming a target pattern at an exposure dose of preferably about 1 to 200 mJ/cm², more preferably about 10 to 100 mJ/cm². When EB is employed as the high-energy beam, the exposure dose is preferably about 0.1 to 100 μC/cm², more preferably about 0.5 to 50 μC/cm², and the writing is performed directly or while using a mask for forming a target pattern. Note that the inventive resist material is particularly suitable for fine patterning with a KrF excimer laser beam, an ArF excimer laser beam, an EB, an EUV, X-ray, soft X-ray, γ-ray, or synchrotron radiation among the high-energy beams, and is particularly suitable for fine patterning with an EB or an EUV.

The exposure may be followed by post-exposure baking (PEB) on a hot plate or in an oven, preferably at 50 to 150° C. for 10 seconds to 30 minutes, more preferably 60 to 120° C. for 30 seconds to 20 minutes.

[Step (iii)]

After the exposure or PEB, the exposed resist film is developed using a developer of a 0.1 to 10 mass %, preferably 2 to 5 mass %, aqueous alkaline solution, such as tetramethylammonium hydroxide (TMAH), tetraethylammonium hydroxide, tetrapropylammonium hydroxide, and tetrabutylammonium hydroxide, for 3 seconds to 3 minutes, preferably 5 seconds to 2 minutes, by a conventional technique, such as a dip, puddle, or spray method. Thereby, the portion irradiated with the light is dissolved by the developer, while the unexposed portion remains undissolved. In this way, the target positive pattern is formed on the substrate.

### EXAMPLE

Hereinafter, the present invention will be described specifically with reference to Examples and Comparative Examples. However, the present invention is not limited to these Examples.

### [Examples 1-1 to 1-20 and Comparative Examples 1-1 to 1-10] Preparation of Resist Compositions

According to the composition shown in Tables 1 and 2, components were dissolved in a solvent in which 50 ppm of a surfactant PolyFox PF-636 manufactured by OMNOVA Solutions Inc. had been dissolved. The resulting solution was filtered through a filter having a pore size of 0.2 μm to prepare each resist composition (for Examples: R-1 to R-20, and for Comparative Examples: cR-1 to cR-10). The contents of each resist composition are shown in Tables 1 and 2.

The components in Tables 1 and 2 are as follows.

### Organic Solvents:

PGMEA (propylene glycol monomethyl ether acetate)
DAA (diacetone alcohol)
EL (ethyl lactate)
(In the Tables, respectively shown as P, D, and E)
   Base Polymers: P-1 to P-9, cP-1, and cP-2

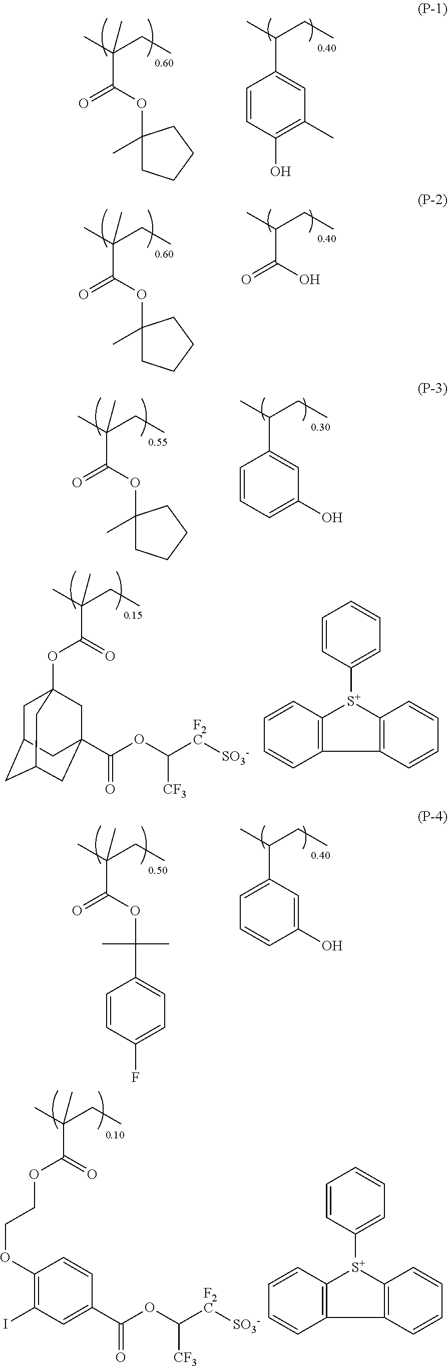

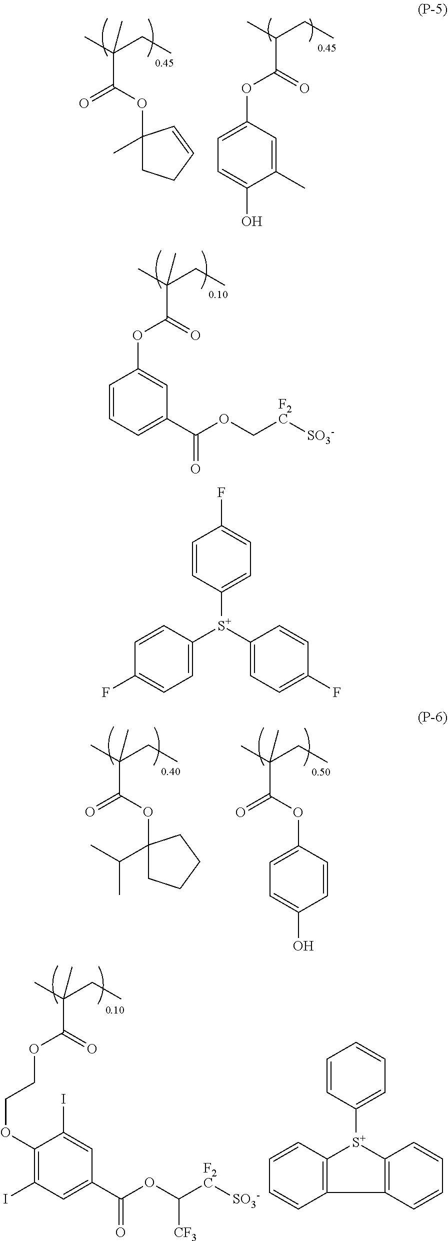

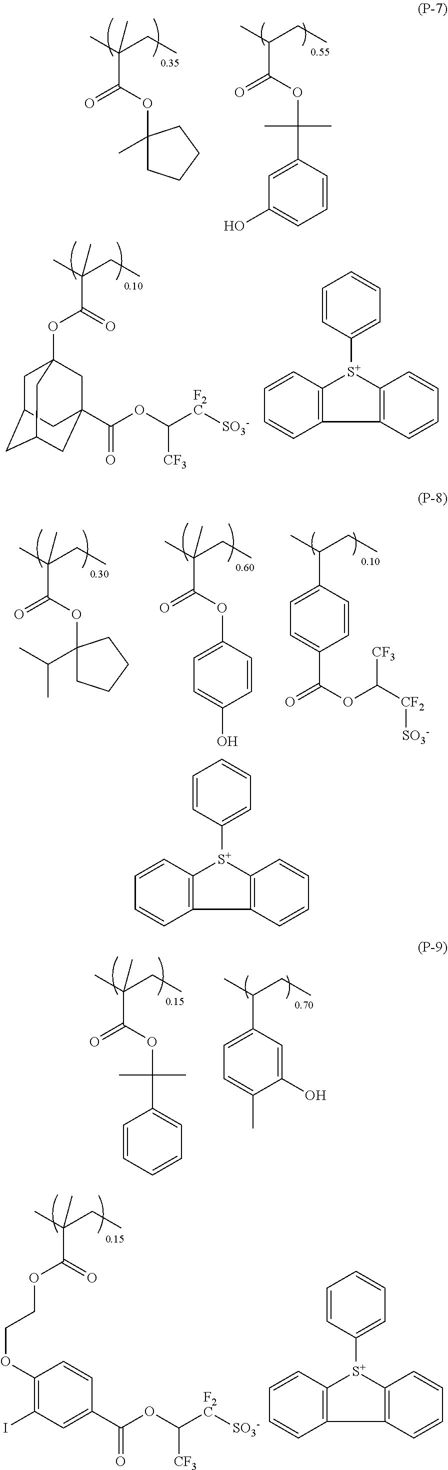

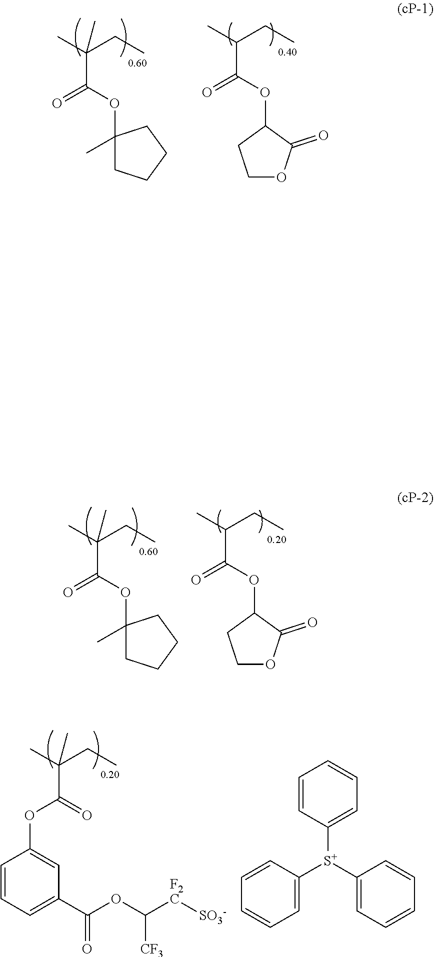

The weight-average molecular weight (Mw) and the molecular weight distribution (Mw/Mn) of the above base polymers (P-1 to P-9, cP-1, and cP-2) were respectively as follows.

| | | |
|---|---|---|
| P-1 | Mw: 8100 | Mw/Mn: 1.83 |
| P-2 | Mw: 7500 | Mw/Mn: 1.89 |
| P-3 | Mw: 8600 | Mw/Mn: 1.66 |
| P-4 | Mw: 10100 | Mw/Mn: 1.58 |
| P-5 | Mw: 9800 | Mw/Mn: 1.72 |
| P-6 | Mw: 11200 | Mw/Mn: 1.50 |
| P-7 | Mw: 8700 | Mw/Mn: 1.75 |
| P-8 | Mw: 9300 | Mw/Mn: 1.63 |
| P-9 | Mw: 10400 | Mw/Mn: 1.54 |
| cP-1 | Mw: 7900 | Mw/Mn: 1.87 |
| cP-2 | Mw: 9900 | Mw/Mn: 1.85 |

### Acid Generators: PAG-1 and PAG-2

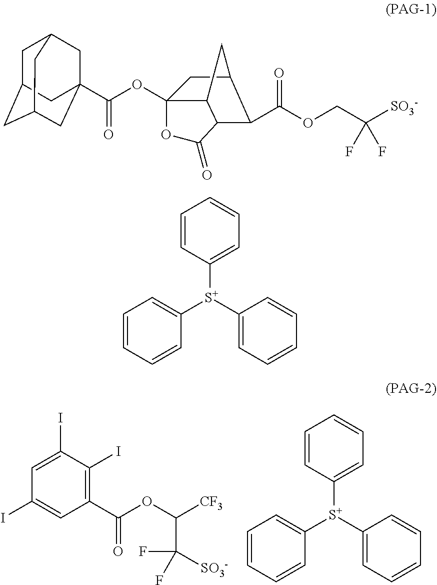

Quenchers: Q-1 to Q-7, cQ-1, and cQ-2

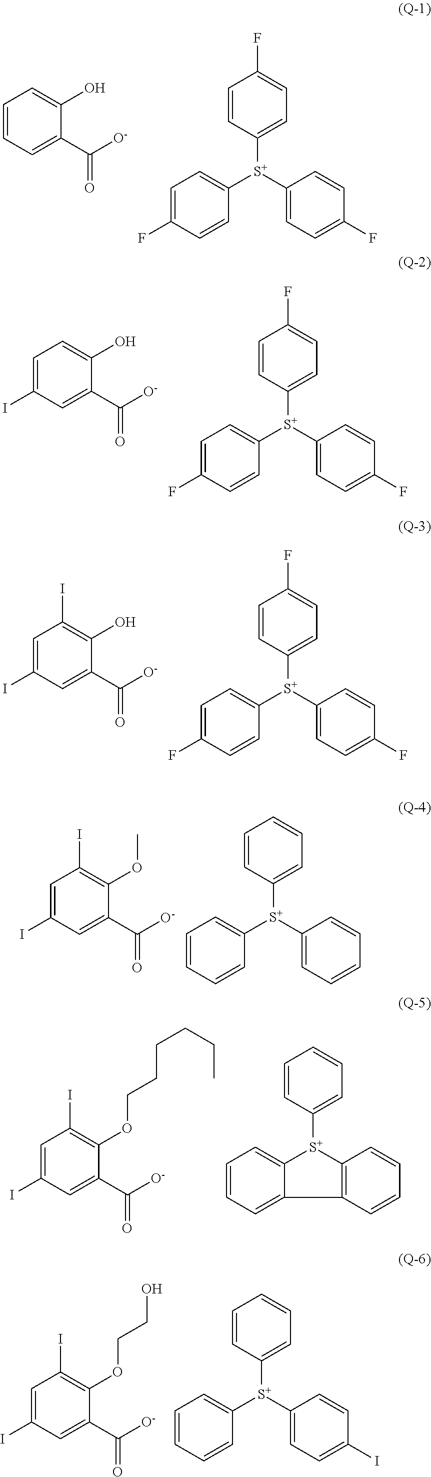

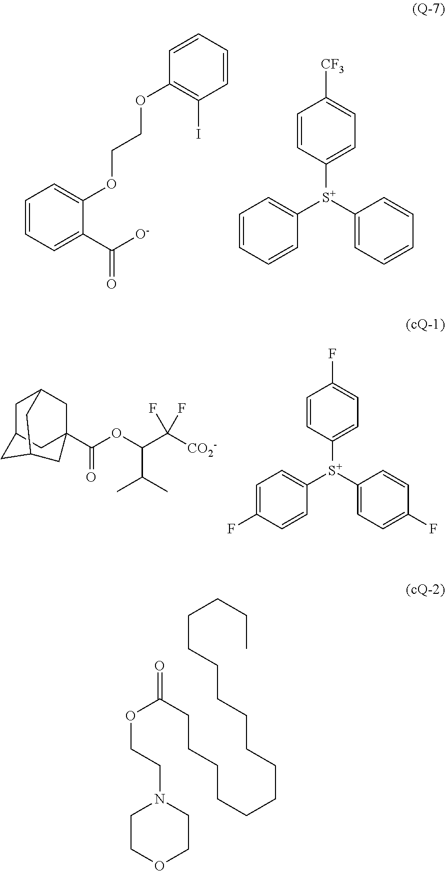

Crosslinking Agents: X-1 to X-4 and cX-1

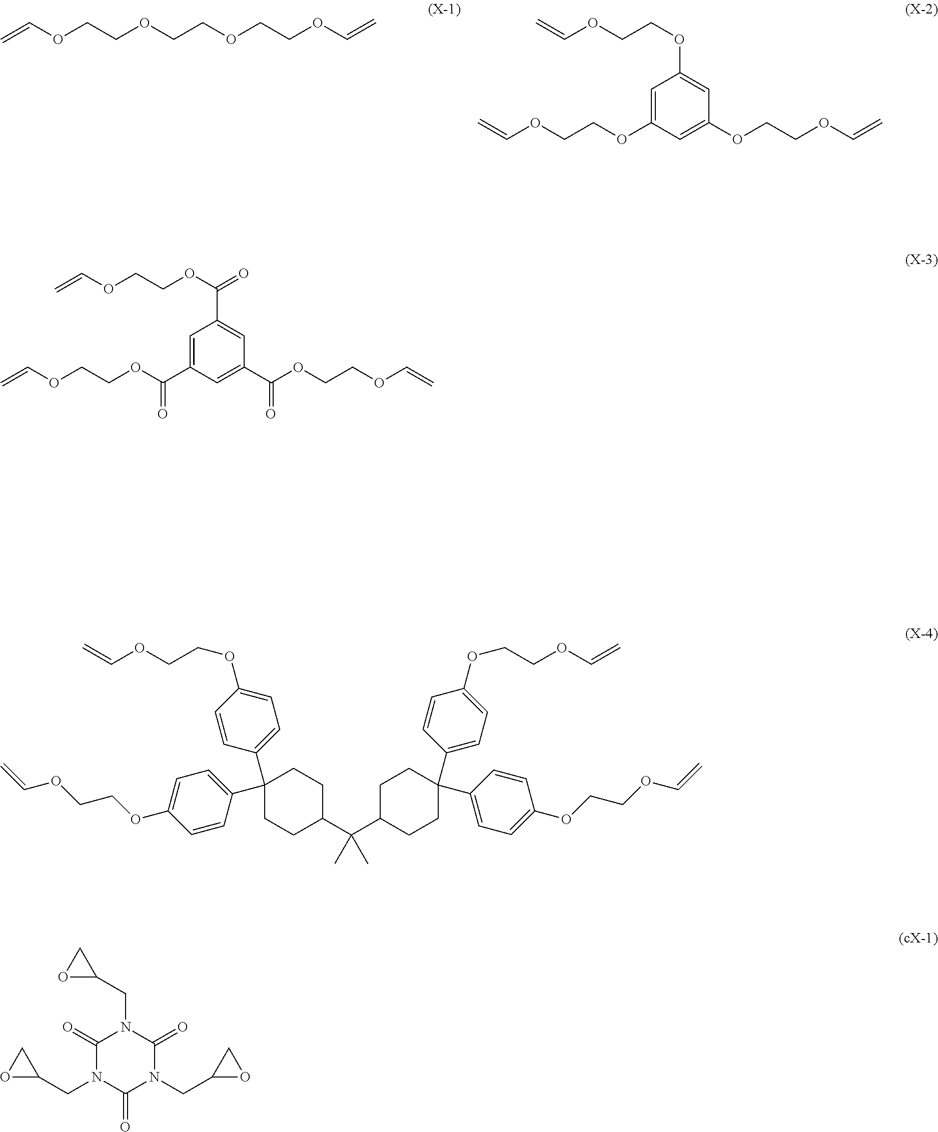 [SMILES: C=COCCOCCOCCOC=C ; C=COCCOc1cc(OCCOC=C)cc(OCCOC=C)c1 ; C=COCCOC(=O)c1cc(C(=O)OCCOC=C)cc(C(=O)OCCOC=C)c1 ; C=COCCOc1ccc(C2(c3ccc(OCCOC=C)cc3)CCC(C(C)(C)C3CCC(c4ccc(OCCOC=C)cc4)(c4ccc(OCCOC=C)cc4)CC3)CC2)cc1 ; O=c1n(CC2CO2)c(=O)n(CC2CO2)c(=O)n1CC1CO1]

### Thermal Acid Generators: T-1 to T-4

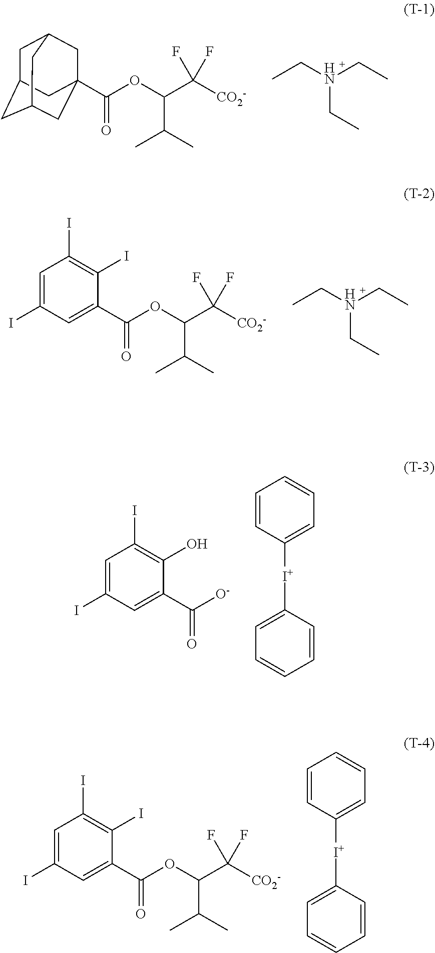

TABLE 1

| | | | Photo- | | Cross- | Thermal | |
|---|---|---|---|---|---|---|---|
| | | Base | acid | | linking | acid | |
| | | polymer | generator | Quencher | agent | generator | Solvent |
| | Resist | (parts | (parts | (parts | (parts | (parts | (parts |
| | composition | by mass) | by mass) | by mass) | by mass) | by mass) | by mass *¹) |
| Example | R-1 | P-1 | PAG-1 | Q-2 | X-1 | T-1 | P/D = 7/3 |
| 1-1 | | (80) | (20) | (15) | (7) | (1) | (3670) |
| Example | R-2 | P-2 | PAG-2 | Q-2 | X-1 | T-1 | P/D = 7/3 |
| 1-2 | | (80) | (25) | (15) | (7) | (1) | (3670) |
| Example | R-3 | P-3 | | Q-1 | X-2 | T-2 | P/D = 7/3 |
| 1-3 | | (80) | | (13) | (5) | (1) | (3670) |
| Example | R-4 | P-4 | | Q-3 | X-2 | T-2 | P/D/E = 4/1/5 |
| 1-4 | | (80) | | (14) | (7) | (1) | (3440) |
| Example | R-5 | P-5 | | Q-3 | X-3 | T-2 | P/D/E = 4/1/5 |
| 1-5 | | (80) | | (14) | (7) | (1) | (3440) |
| Example | R-6 | P-6 | | Q-3 | X-3 | T-2 | P/D/E = 4/1/5 |
| 1-6 | | (80) | | (14) | (8) | (1) | (3440) |
| Example | R-7 | P-7 | | Q-3 | X-4 | T-2 | P/D/E = 4/1/5 |
| 1-7 | | (80) | | (14) | (15) | (1) | (3440) |
| Example | R-8 | P-8 | | Q-3 | X-4 | T-2 | P/D/E = 4/1/5 |
| 1-8 | | (80) | | (16) | (15) | (1) | (3440) |
| Example | R-9 | P-9 | | Q-3 | X-2 | T-2 | P/D/E = 4/1/5 |
| 1-9 | | (80) | | (18) | (12) | (1) | (3440) |
| Example | R-10 | P-4 | | Q-4 | X-2 | T-3 | P/D/E = 4/1/5 |
| 1-10 | | (80) | | (15) | (7) | (2) | (3440) |
| Example | R-11 | P-4 | | Q-5 | X-2 | T-3 | P/D/E = 4/1/5 |
| 1-11 | | (80) | | (16) | (7) | (2) | (3440) |
| Example | R-12 | P-4 | | Q-6 | X-3 | T-4 | P/D/E = 4/1/5 |
| 1-12 | | (80) | | (15) | (7) | (3) | (3440) |
| Example | R-13 | P-4 | | Q-7 | X-3 | T-4 | P/D/E = 4/1/5 |
| 1-13 | | (80) | | (20) | (7) | (3) | (3440) |
| Example | R-14 | P-5 | | Q-1 | X-2 | T-2 | P/D/E = 4/1/5 |
| 1-14 | | (80) | | (13) | (7) | (1) | (3440) |
| Example | R-15 | P-5 | | Q-3 | X-2 | T-2 | P/D/E = 4/1/5 |
| 1-15 | | (80) | | (14) | (7) | (1) | (3440) |
| Example | R-16 | P-5 | | Q-4 | X-2 | T-2 | P/D/E = 4/1/5 |
| 1-16 | | (80) | | (15) | (7) | (1) | (3440) |
| Example | R-17 | P-6 | | Q-1 | X-2 | T-2 | P/D/E = 4/1/5 |
| 1-17 | | (80) | | (13) | (8) | (1) | (3440) |
| Example | R-18 | P-6 | | Q-2 | X-2 | T-2 | P/D/E = 4/1/5 |
| 1-18 | | (80) | | (15) | (8) | (1) | (3440) |
| Example | R-19 | P-6 | | Q-3 | X-2 | T-2 | P/D/E = 4/1/5 |
| 1-19 | | (80) | | (14) | (8) | (1) | (3440) |
| Example | R-20 | P-6 | | Q-3 | X-4 | T-2 | P/D/E = 4/1/5 |
| 1-20 | | (80) | | (14) | (12) | (1) | (3440) |

*¹ Examples 1-1 to 1-3: P/D = 2570/1100
Examples 1-4 to 1-20: P/D/E = 1380/340/1720

TABLE 2

| | | | Photo- | | Cross- | Thermal | |
|---|---|---|---|---|---|---|---|
| | | Base | acid | | linking | acid | |
| | | polymer | generator | Quencher | agent | generator | Solvent |
| | Resist | (parts | (parts | (parts | (parts | (parts | (parts |
| | composition | by mass) | by mass) | by mass) | by mass) | by mass) | by mass *²) |
| Comparative | cR-1 | cP-1 | PAG-1 | Q-2 | X-1 | T-1 | P/D = 7/3 |
| Example | | (80) | (20) | (15) | (7) | (1) | (3670) |
| 1-1 | | | | | | | |
| Comparative | cR-2 | cP-1 | PAG-2 | Q-2 | X-1 | T-1 | P/D = 7/3 |
| Example | | (80) | (25) | (15) | (7) | (1) | (3670) |
| 1-2 | | | | | | | |
| Comparative | cR-3 | cP-2 | | Q-3 | X-2 | | P/D = 7/3 |
| Example | | (80) | | (14) | (7) | | (3670) |
| 1-3 | | | | | | | |
| Comparative | cR-4 | cP-2 | | Q-3 | X-2 | T-2 | P/D/E = 4/1/5 |
| Example | | (80) | | (14) | (7) | (1) | (3440) |
| 1-4 | | | | | | | |
| Comparative | cR-5 | P-1 | PAG-1 | Q-2 | | | P/D/E = 4/1/5 |
| Example | | (80) | (20) | (15) | | | (3440) |
| 1-5 | | | | | | | |
| Comparative | cR-6 | P-1 | PAG-1 | Q-2 | X-2 | | P/D/E = 4/1/5 |
| Example | | (80) | (20) | (15) | (10) | | (3440) |
| 1-6 | | | | | | | |
| Comparative | cR-7 | P-3 | | Q-2 | cX-1 | | P/D/E = 4/1/5 |
| Example | | (80) | | (15) | (5) | | (3440) |
| 1-7 | | | | | | | |
| Comparative | cR-8 | P-3 | | cQ-2 | X-2 | T-2 | P/D/E = 4/1/5 |
| Example | | (80) | | (8) | (10) | (1) | (3440) |
| 1-8 | | | | | | | |
| Comparative | cR-9 | P-1 | PAG-1 | cQ-1 | | | P/D/E = 4/1/5 |
| Example | | (80) | (20) | (20) | | | (3440) |
| 1-9 | | | | | | | |
| Comparative | cR-10 | P-3 | | cQ-1 | | | P/D/E = 4/1/5 |
| Example | | (80) | | (20) | | | (3440) |
| 1-10 | | | | | | | |

*² Comparative Examples 1-1 to 1-3: P/D = 2570/1100
Comparative Examples 1-4 to 1-10: P/D/E = 1380/340/1720

### [Examples 2-1 to 2-20 and Comparative Examples 2-1 to 2-10] Heat Resistance Evaluation

Each of the resist compositions R-1 to R-20 and cR-1 to cR-10 was respectively applied onto an 8-inch wafer by spin-coating, and then baked using a hot plate at the temperature shown in Tables 3 and 4 for 60 seconds to form a resist film. After that, the resist film was removed from the wafer by using a scraper to obtain a sample for evaluation. The sample for heat resistance evaluation was subjected to differential scanning calorimetry (DSC) to measure the glass transition point. To measure the glass transition point, a differential scanning calorimeter (Thermo plus EVO2 DSC8231) manufactured by Rigaku Corporation was used.

The temperature at which a shift in the baseline was observed in the DSC curve was defined as the glass transition temperature, and the heat resistance of the resist was evaluated based on the following criteria. The results of Examples 2-1 to 2-20 are shown in Table 3, and the results of Comparative Examples 2-1 to 2-10 are shown in Table 4.

### (Criteria)

Excellent: the glass transition temperature was 110° C. or higher
Good: the glass transition temperature was 105° C. or higher
Poor: the glass transition temperature was lower than 105° C.

TABLE 3

| | | Baking | | |
|---|---|---|---|---|
| | Resist | temperature | Tg | |
| | composition | (° C.) | (° C.) | Evaluation |
| Example 2-1 | R-1 | 130 | 107 | Good |
| Example 2-2 | R-2 | 130 | 106 | Good |
| Example 2-3 | R-3 | 130 | 105 | Good |
| Example 2-4 | R-4 | 130 | 113 | Excellent |
| Example 2-5 | R-5 | 130 | 111 | Excellent |
| Example 2-6 | R-6 | 130 | 114 | Excellent |
| Example 2-7 | R-7 | 130 | 115 | Excellent |
| Example 2-8 | R-8 | 130 | 115 | Excellent |
| Example 2-9 | R-9 | 130 | 116 | Excellent |
| Example 2-10 | R-10 | 130 | 113 | Excellent |
| Example 2-11 | R-11 | 130 | 112 | Excellent |
| Example 2-12 | R-12 | 130 | 114 | Excellent |
| Example 2-13 | R-13 | 130 | 111 | Excellent |
| Example 2-14 | R-14 | 130 | 115 | Excellent |
| Example 2-15 | R-15 | 130 | 117 | Excellent |
| Example 2-16 | R-16 | 130 | 120 | Excellent |
| Example 2-17 | R-17 | 130 | 115 | Excellent |
| Example 2-18 | R-18 | 130 | 116 | Excellent |
| Example 2-19 | R-19 | 130 | 116 | Excellent |
| Example 2-20 | R-20 | 130 | 122 | Excellent |

TABLE 4

| | | Baking | | |
|---|---|---|---|---|
| | Resist | temperature | Tg | |
| | composition | (° C.) | (° C.) | Evaluation |
| Comparative | cR-1 | 130 | 101 | Poor |
| Example 2-1 | | | | |
| Comparative | cR-2 | 130 | 100 | Poor |
| Example 2-2 | | | | |
| Comparative | cR-3 | 130 | 95 | Poor |
| Example 2-3 | | | | |
| Comparative | cR-4 | 130 | 96 | Poor |
| Example 2-4 | | | | |
| Comparative | cR-5 | 130 | 102 | Poor |
| Example 2-5 | | | | |
| Comparative | cR-6 | 130 | 96 | Poor |
| Example 2-6 | | | | |
| Comparative | cR-7 | 130 | 98 | Poor |
| Example 2-7 | | | | |
| Comparative | cR-8 | 130 | 97 | Poor |
| Example 2-8 | | | | |
| Comparative | cR-9 | 130 | 103 | Poor |
| Example 2-9 | | | | |
| Comparative | cR-10 | 130 | 104 | Poor |
| Example 2-10 | | | | |

### [Examples 3-1 to 3-20 and Comparative Examples 3-1 to 3-10] Dissolution Contrast Evaluation

A Si substrate with a silicon-containing spin-on hard mask SHB-A940 (silicon content: 43 mass %) manufactured by Shin-Etsu Chemical Co., Ltd. formed to have a film thickness of 20 nm was spin-coated with one of the resist compositions R-1 to R-20 and cR-1 to cR-10, and the resist composition was prebaked by using a hot plate at 130° C. for 60 seconds to form a resist film having a thickness of 50 nm. The resist film was exposed using a KrF exposure apparatus (S206D manufactured by Nikon Corporation), followed by PEB on a hot plate at 95° C. for 60 seconds and development with a 2.38 mass % aqueous TMAH solution for 30 seconds. The resist film thickness after this development treatment was measured, the relationship between the exposure dose and the resist film thickness after the development treatment was plotted, and the dissolution contrast was analyzed. Furthermore, as Examples 3-1 to 3-20 and Comparative Examples 3-1 to 3-10, the contrast was evaluated according to the following criteria. To measure the film thickness, a film thickness meter VM-2210, manufactured by Hitachi High-Technologies Corp., was used.

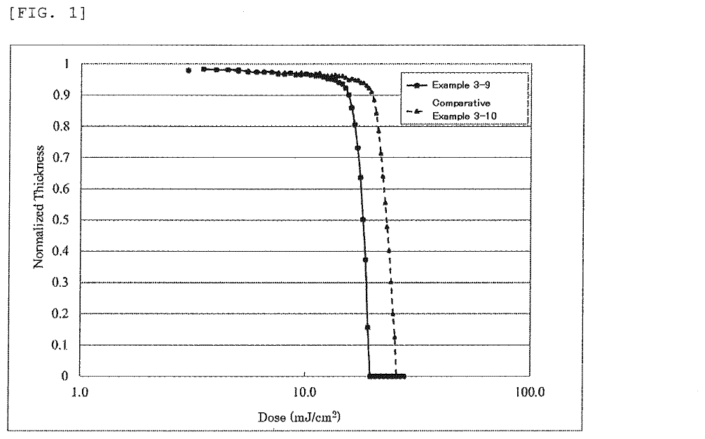

As representative compositions in the dissolution contrast evaluation, the contrast curves of the resist films of Example 3-9 and Comparative Example 3-10 are shown in FIG. 1. Note that the vertical axis in FIG. 1 shows a value obtained by normalizing the film thickness after the development treatment by the film thickness before the treatment. The value of the contrast in Tables 5 and 6 shows the gradient of the change in film thickness depending on the exposure dose where the developer solubility of the resist film changes rapidly. In the interval from when the film thickness becomes 80% or less of the initial film thickness to when the film is completely dissolved, a contrast value is defined as the gradient when the horizontal axis shows the logarithm of the exposure dose and the vertical axis shows the normalized film thickness, and regarding the judgement of the contrast of the resist film formed from each resist composition, evaluation was carried out as follows based on the absolute value of the contrast value. The results of Examples 3-1 to 3-20 are shown in Table 5, and the results of Comparative Examples 3-1 to 3-10 are shown in Table 6.

### (Criteria)

Excellent: the absolute value of the contrast value was 4.5 or higher
Good: the absolute value of the contrast value was 4 or higher and lower than 4.5
Poor: the absolute value of the contrast value was lower than 4

TABLE 5

| | Resist | Contrast | |
|---|---|---|---|
| | composition | value | Evaluation |
| Example 3-1 | R-1 | 4.1 | Good |
| Example 3-2 | R-2 | 4.2 | Good |
| Example 3-3 | R-3 | 5.5 | Excellent |
| Example 3-4 | R-4 | 5.2 | Excellent |
| Example 3-5 | R-5 | 5.3 | Excellent |
| Example 3-6 | R-6 | 5.4 | Excellent |
| Example 3-7 | R-7 | 5.8 | Excellent |
| Example 3-8 | R-8 | 4.7 | Excellent |
| Example 3-9 | R-9 | 5.1 | Excellent |
| Example 3-10 | R-10 | 5.0 | Excellent |
| Example 3-11 | R-11 | 4.9 | Excellent |
| Example 3-12 | R-12 | 4.9 | Excellent |
| Example 3-13 | R-13 | 4.7 | Excellent |
| Example 3-14 | R-14 | 4.8 | Excellent |
| Example 3-15 | R-15 | 5.2 | Excellent |
| Example 3-16 | R-16 | 4.9 | Excellent |
| Example 3-17 | R-17 | 4.5 | Excellent |
| Example 3-18 | R-18 | 4.9 | Excellent |
| Example 3-19 | R-19 | 5.1 | Excellent |
| Example 3-20 | R-20 | 4.6 | Excellent |

TABLE 6

| | Resist | Contrast | |
|---|---|---|---|
| | composition | value | Evaluation |
| Comparative | cR-1 | 3.0 | Poor |
| Example 3-1 | | | |
| Comparative | cR-2 | 3.1 | Poor |
| Example 3-2 | | | |
| Comparative | cR-3 | 2.6 | Poor |
| Example 3-3 | | | |
| Comparative | cR-4 | 2.7 | Poor |
| Example 3-4 | | | |
| Comparative | cR-5 | 3.2 | Poor |
| Example 3-5 | | | |
| Comparative | cR-6 | 3.9 | Poor |
| Example 3-6 | | | |
| Comparative | cR-7 | 3.5 | Poor |
| Example 3-7 | | | |
| Comparative | cR-8 | 3.4 | Poor |
| Example 3-8 | | | |
| Comparative | cR-9 | 2.9 | Poor |
| Example 3-9 | | | |
| Comparative | cR-10 | 3.8 | Poor |
| Example 3-10 | | | |

### [Examples 4-1 to 4-20 and Comparative Examples 4-1 to 4-5] EB Lithography Evaluation

Each of the resist compositions R-1 to R-20 and cR-1 to cR-10 was respectively applied by spin-coating onto an antireflective film DUV-42, available from Nissan Chemical Corporation, formed on an 8-inch wafer with a film thickness of 61 nm, and then prebaked using a hot plate at 130° C. for 60 seconds to form a resist film having a thickness of 50 nm. The resist film was subjected to exposure of an LS pattern having a size of 18 nm on the wafer and a pitch of 36 nm by using an electron beam writing apparatus (ELS-F125, acceleration voltage: 125 kV) manufactured by ELIONIX INC., and after the exposure, PEB was performed at 90° C. for 60 seconds. After the PEB, puddle development was performed with a 2.38 mass % aqueous TMAH solution for 30 seconds, rinsing was performed with an aqueous solution of a surfactant-containing rinsing material, spin-drying was performed, and thus, a positive pattern was obtained. The developed LS pattern was observed with CD-SEM (S9380) manufactured by Hitachi High-Technologies Corp., and the optimum exposure dose Eop (mJ/cm²) at which the LS pattern having a line width of 18 nm and a pitch of 36 nm was obtained was determined as sensitivity. In addition, a tripled value (3a) of a standard variation (a) calculated from the measurement results of the pattern size was determined as the variation in pattern width (LWR). The results of Examples 4-1 to 4-20 are shown in Table 7, and the results of Comparative Examples 4-1 to 4-10 are shown in Table 8.

### (Criteria)

Excellent: the LWR value was less than 4.0
Good: the LWR value was 4.0 or more and less than 4.5
Poor: the LWR value was 4.5 or more

TABLE 7

| | Resist | | |
|---|---|---|---|
| | composition | LWR | Evaluation |
| Example 4-1 | R-1 | 4.4 | Good |
| Example 4-2 | R-2 | 4.3 | Good |
| Example 4-3 | R-3 | 3.9 | Excellent |
| Example 4-4 | R-4 | 3.2 | Excellent |
| Example 4-5 | R-5 | 3.5 | Excellent |
| Example 4-6 | R-6 | 3.0 | Excellent |
| Example 4-7 | R-7 | 3.5 | Excellent |
| Example 4-8 | R-8 | 3.4 | Excellent |
| Example 4-9 | R-9 | 4.1 | Good |
| Example 4-10 | R-10 | 3.3 | Excellent |
| Example 4-11 | R-11 | 3.1 | Excellent |
| Example 4-12 | R-12 | 3.2 | Excellent |
| Example 4-13 | R-13 | 3.4 | Excellent |
| Example 4-14 | R-14 | 3.7 | Excellent |
| Example 4-15 | R-15 | 3.6 | Excellent |
| Example 4-16 | R-16 | 3.5 | Excellent |
| Example 4-17 | R-17 | 3.5 | Excellent |
| Example 4-18 | R-18 | 3.4 | Excellent |
| Example 4-19 | R-19 | 3.0 | Excellent |
| Example 4-20 | R-20 | 3.1 | Excellent |

TABLE 8

| | Resist | | |
|---|---|---|---|
| | composition | LWR | Evaluation |
| Comparative | cR-1 | 6.0 | Poor |
| Example 4-1 | | | |
| Comparative | cR-2 | 5.7 | Poor |
| Example 4-2 | | | |
| Comparative | cR-3 | 5.2 | Poor |
| Example 4-3 | | | |
| Comparative | cR-4 | 5.3 | Poor |
| Example 4-4 | | | |
| Comparative | cR-5 | 4.5 | Poor |
| Example 4-5 | | | |
| Comparative | cR-6 | 4.8 | Poor |
| Example 4-6 | | | |
| Comparative | cR-7 | 4.5 | Poor |
| Example 4-7 | | | |
| Comparative | cR-8 | 5.9 | Poor |
| Example 4-8 | | | |
| Comparative | cR-9 | 5.5 | Poor |
| Example 4-9 | | | |
| Comparative | cR-10 | 5.1 | Poor |
| Example 4-10 | | | |

From the results shown in Tables 3 to 8 and FIG. 1, it was shown that the inventive resist materials were excellent in heat resistance, resolution, and LWR. On the other hand, in the resist compositions cR-1 to cR-4 (Comparative Examples 1-1 to 1-4), the base polymer did not contain a repeating unit containing a particular reactive group, and therefore, resulted in poor heat resistance (glass transition temperature), resolution, and LWR. Meanwhile, the resist compositions cR-5 to cR-10 (Comparative Examples 1-5 to 1-10) also resulted in poor heat resistance (glass transition temperature), resolution, and LWR, since the resist compositions did not contain one or more of the quencher, crosslinking agent, and thermal acid generator of the present invention. From the above, it was revealed that the inventive resist material can achieve low edge roughness, low size variation, excellent resolution, and favorable heat resistance by containing all of a particular base polymer (P), a particular crosslinking agent, a thermal acid generator, a particular quencher, and an organic solvent.

The present description includes the following inventions.

[1]: A resist material comprising:
a base polymer (P) containing a repeating unit (A) containing a reactive group and represented by the following formula (a1) or (a2), and a repeating unit (B) having an acid-decomposable group;
a crosslinking agent having a structure represented by the following formula (1);
a thermal acid generator;
a photodecomposable quencher represented by the following formula (2); and
an organic solvent,

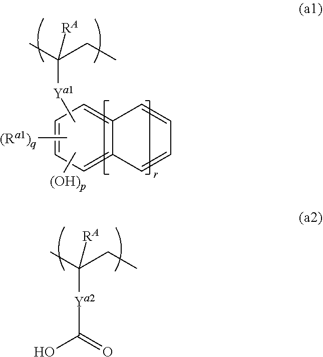

wherein each R^{A} independently represents a hydrogen atom or a methyl group, Y^{a1} and Y^{a2} each independently represent a single bond, a phenylene group, a naphthylene group, or a linking group having 1 to 14 carbon atoms and having an ester bond, an ether bond, an amide bond, or a lactone ring, R^{a1} represents a hydrogen atom, a fluorine atom, or a saturated hydrocarbyl group having 1 to 6 carbon atoms, R^{a1} and Y^{a1} optionally being bonded to each other to form a ring together with the carbon atoms on the aromatic ring bonded thereto, “p” represents 1 or 2, “q” represents an integer of 0 to 4, 1≤p+q≤5, and “r” represents 0 or 1,

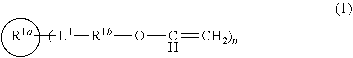

wherein R^{1a} represents an organic group optionally having a substituent, L¹ represents a linking group selected from a single bond, an ester bond, and an ether bond, R^{1b} represents a single bond or a divalent organic group, and “n” represents an integer of 2 to 4,

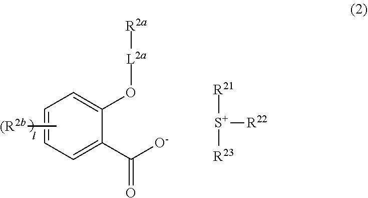

wherein R²¹ to R²³ each independently represent a monovalent hydrocarbon group having 1 to 20 carbon atoms and optionally containing a heteroatom, any two of R²¹, R²², and R²³ optionally being bonded to each other to form a ring together with the sulfur atom bonded thereto, “I” represents an integer of 0 to 4, R^{2b} represents a halogen atom, a hydroxy group, a nitro group, a hydrocarbon group having 1 to 20 carbon atoms and optionally having a substituent, an alkoxy group having 1 to 18 carbon atoms and optionally having a substituent, an amino group optionally having a substituent, or a phenyl group optionally having a substituent, when “I” is 2 or more, the R^{2b}s optionally being different from each other, L^{2a} represents a single bond, an ester bond, or a divalent linking group having 1 to 8 carbon atoms, and R^{2a} represents a hydrogen atom or a hydrocarbon group having 1 to 18 carbon atoms and optionally having a substituent, R^{2a} and R^{2b} optionally being bonded to each other to form a ring together with the carbon atoms bonded thereto.

[2]: The resist material according to the above [1], wherein the base polymer (P) contains a repeating unit (C) having a structural site which is decomposed by irradiation with an active ray or a radiant ray to generate an acid.

[3]: The resist material according to the above [2], wherein the repeating unit (C) contained in the base polymer (P) is represented by the following formula (c),

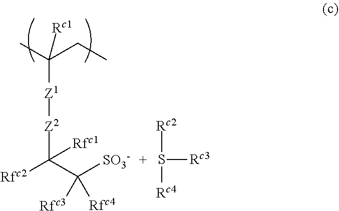

wherein R^{c1} represents a hydrogen atom or a methyl group; Z¹ represents a single bond or an ester bond; Z² represents a single bond or a divalent organic group having 1 to 20 carbon atoms and optionally containing an ester bond, an ether bond, a lactone ring, an amide bond, a sultone ring, or an iodine atom; Rf^{c1} to Rf^{c4} each independently represent a hydrogen atom, a fluorine atom, or a trifluoromethyl group, provided that at least one of Rf^{c1} to Rf^{c4} contains a fluorine atom; and R^{c2} to R^{c4} each independently represent a monovalent hydrocarbon group having 1 to 20 carbon atoms and optionally containing a heteroatom, any two of R^{c2}, R^{c3}, and R^{c4} optionally being bonded to each other to form a ring together with the sulfur atom bonded thereto.

[4]: The resist material according to any one of the above [1] to [3], wherein the repeating unit (B) contained in the base polymer (P) is represented by the following formula (b),

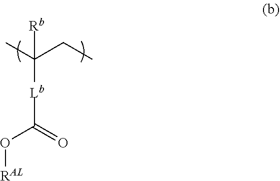

wherein R^{b} represents a hydrogen atom or a methyl group; L^{b} represents a single bond or a divalent linking group having 1 to 15 carbon atoms and including at least one of a phenylene group, a naphthylene group, an ester bond, an ether bond, a lactone ring, an amide group, and a heteroatom; and R^{AL} represents an acid-labile group.

[5]: The resist material according to any one of the above [1] to [4], wherein the repeating unit (A) contained in the base polymer (P) is represented by the formula (a1), and is contained at a percentage of 30 mol % or more based on a total amount of the repeating units in the base polymer (P).

[6]: A patterning process comprising the steps of:
forming a resist film on a substrate by using the resist material according to any one of the above [1] to [5];
exposing the resist film to a high-energy beam; and
developing the exposed resist film by using a developer.

[7]: The patterning process according to the above [6], wherein, in the step of forming the resist film, a baking temperature is set to 130° C. or higher.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A resist material comprising:
a base polymer (P) containing a repeating unit (A) containing a reactive group and represented by the following formula (a1) or (a2), and a repeating unit (B) having an acid-decomposable group;
a crosslinking agent having a structure represented by the following formula (1);
a thermal acid generator;
a photodecomposable quencher represented by the following formula (2); and
an organic solvent, 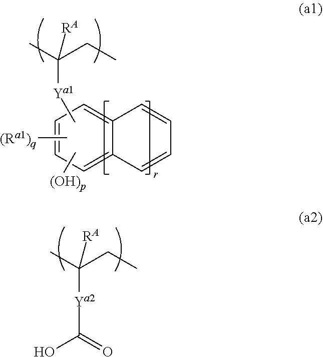
wherein each R^{A} independently represents a hydrogen atom or a methyl group, Y^{a1} and Y^{a2} each independently represent a single bond, a phenylene group, a naphthylene group, or a linking group having 1 to 14 carbon atoms and having an ester bond, an ether bond, an amide bond, or a lactone ring, R^{a1} represents a hydrogen atom, a fluorine atom, or a saturated hydrocarbyl group having 1 to 6 carbon atoms, R^{a1} and Y^{a1} optionally being bonded to each other to form a ring together with the carbon atoms on the aromatic ring bonded thereto, “p” represents 1 or 2, “q” represents an integer of 0 to 4, 1≤p+q≤5, and “r” represents 0 or 1, 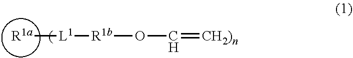
wherein R^{1a} represents an organic group optionally having a substituent, L¹ represents a linking group selected from a single bond, an ester bond, and an ether bond, R^{1b} represents a single bond or a divalent organic group, and “n” represents an integer of 2 to 4, 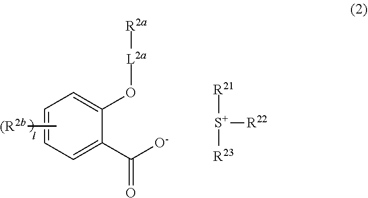
wherein R²¹ to R²³ each independently represent a monovalent hydrocarbon group having 1 to 20 carbon atoms and optionally containing a heteroatom, any two of R²¹, R²², and R²³ optionally being bonded to each other to form a ring together with the sulfur atom bonded thereto, “I” represents an integer of 0 to 4, R^{2b} represents a halogen atom, a hydroxy group, a nitro group, a hydrocarbon group having 1 to 20 carbon atoms and optionally having a substituent, an alkoxy group having 1 to 18 carbon atoms and optionally having a substituent, an amino group optionally having a substituent, or a phenyl group optionally having a substituent, when “I” is 2 or more, the R^{2b}s optionally being different from each other, L^{2a} represents a single bond, an ester bond, or a divalent linking group having 1 to 8 carbon atoms, and R^{2a} represents a hydrogen atom or a hydrocarbon group having 1 to 18 carbon atoms and optionally having a substituent, R^{2a} and R^{2b} optionally being bonded to each other to form a ring together with the carbon atoms bonded thereto.

2. The resist material according to claim 1, wherein the base polymer (P) contains a repeating unit (C) having a structural site which is decomposed by irradiation with an active ray or a radiant ray to generate an acid.

3. The resist material according to claim 2, wherein the repeating unit (C) contained in the base polymer (P) is represented by the following formula (c), 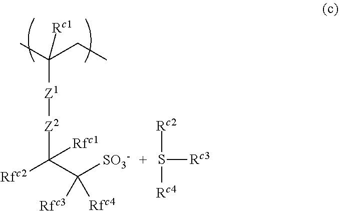
wherein R^{c1} represents a hydrogen atom or a methyl group; Z¹ represents a single bond or an ester bond; Z² represents a single bond or a divalent organic group having 1 to 20 carbon atoms and optionally containing an ester bond, an ether bond, a lactone ring, an amide bond, a sultone ring, or an iodine atom; Rf^{c1} to Rf^{c4} each independently represent a hydrogen atom, a fluorine atom, or a trifluoromethyl group, provided that at least one of Rf^{c1} to Rf^{c4} contains a fluorine atom; and R^{c2} to R^{c4} each independently represent a monovalent hydrocarbon group having 1 to 20 carbon atoms and optionally containing a heteroatom, any two of R^{c2}, R^{c3}, and R^{c4} optionally being bonded to each other to form a ring together with the sulfur atom bonded thereto.

4. The resist material according to claim 1, wherein the repeating unit (B) contained in the base polymer (P) is represented by the following formula (b), 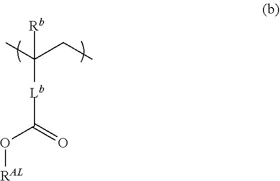
wherein R^{b} represents a hydrogen atom or a methyl group; L^{b} represents a single bond or a divalent linking group having 1 to 15 carbon atoms and including at least one of a phenylene group, a naphthylene group, an ester bond, an ether bond, a lactone ring, an amide group, and a heteroatom; and R^{AL} represents an acid-labile group.

5. The resist material according to claim 1, wherein the repeating unit (A) contained in the base polymer (P) is represented by the formula (a1), and is contained at a percentage of 30 mol % or more based on a total amount of the repeating units in the base polymer (P).

6. A patterning process comprising the steps of:
forming a resist film on a substrate by using the resist material according to claim 1;
exposing the resist film to a high-energy beam; and
developing the exposed resist film by using a developer.

7. A patterning process comprising the steps of:
forming a resist film on a substrate by using the resist material according to claim 2;
exposing the resist film to a high-energy beam; and
developing the exposed resist film by using a developer.

8. A patterning process comprising the steps of:
forming a resist film on a substrate by using the resist material according to claim 3;
exposing the resist film to a high-energy beam; and
developing the exposed resist film by using a developer.

9. A patterning process comprising the steps of:
forming a resist film on a substrate by using the resist material according to claim 4;
exposing the resist film to a high-energy beam; and
developing the exposed resist film by using a developer.

10. A patterning process comprising the steps of:
forming a resist film on a substrate by using the resist material according to claim 5;
exposing the resist film to a high-energy beam; and
developing the exposed resist film by using a developer.

11. The patterning process according to claim 6, wherein, in the step of forming the resist film, a baking temperature is set to 130° C. or higher.

12. The patterning process according to claim 7, wherein, in the step of forming the resist film, a baking temperature is set to 130° C. or higher.

13. The patterning process according to claim 8, wherein, in the step of forming the resist film, a baking temperature is set to 130° C. or higher.

14. The patterning process according to claim 9, wherein, in the step of forming the resist film, a baking temperature is set to 130° C. or higher.

15. The patterning process according to claim 10, wherein, in the step of forming the resist film, a baking temperature is set to 130° C. or higher.
